(19) United States
(12) Patent Application Publication
(10) Pub. No.: US 2026/0281577 A1
(43) Pub. Date: Sep. 17, 2026

(54) IMAGING DEVICE

(71) Applicant: Sony Semiconductor Solutions Corporation, Kanagawa (JP)

(72) Inventors: Youhei Oosako, Kanagawa (JP); Masako Hasegawa, Kanagawa (JP); Shinichirou Etou, Kanagawa (JP)

(21) Appl. No.: 19/472,302

(22) PCT Filed: Mar. 25, 2024
(86) PCT No.: PCT/JP24/11778

§ 371 Date: Oct. 3, 2025

(30) Foreign Application Priority Data
Apr. 12, 2023 (JP) 2023-065249

(51) Int. Cl. H04N 25/709; H04N 25/60; H04N 25/772; H04N 25/778; H04N 25/79; H10F 39/00

(52) U.S. Cl. CPC H04N 25/709; H04N 25/772; H04N 25/778; H04N 25/79; H10F 39/809; H10F 39/811; H04N 25/60

(57) ABSTRACT

Imaging devices with noise suppression are disclosed. In one example, an imaging device includes photoelectric conversion elements that accumulate electric charges according to an amount of incident light arranged in a first direction and an intersecting second direction. Pixel circuits generate an analog pixel signal according to the accumulated electric charges, and a signal line transmits the analog pixel signal output from two or more of the pixel circuits arranged in the second direction. A clip circuit clips a voltage of the signal line to a predetermined lower limit voltage level using a power supply voltage line of any of the two or more of the pixel circuits connected to the signal line.

### TECHNICAL FIELD

The present disclosure relates to an imaging device.

### BACKGROUND ART

Technology is known in which an imaging device that performs imaging by a rolling shutter method has a stacked structure in which a plurality of semiconductor dies is bonded (refer to Patent Document 1). Patent Document 1 discloses an image sensor device configured by bonding three layers of substrates of a first semiconductor die, a second semiconductor die, and a third semiconductor die. In Patent Document 1, a comparator in an AD conversion circuit is divided into a first portion and a second portion, the first portion is formed on the first semiconductor die together with a photodetector, and the second portion is formed on the second semiconductor die.

### CITATION LIST

### Patent Document

Patent Document 1: U.S. Patent Application Publication No. 2020/0258926

### SUMMARY OF THE INVENTION

### Problems to be Solved by the Invention

A pixel signal in the imaging device is supplied to an analog digital (AD) conversion circuit through a vertical signal line, over a distance from one end in a column direction of a pixel array to the other end in the column direction at most. The pixel signal transmitted through the vertical signal line is an analog signal, has a wide signal bandwidth, and is susceptible to noise.

Patent Document 1 discloses a configuration in which digital pixels are configured by a photodetector, a Comparator, and a memory circuit, and the digital pixels are arranged in a matrix array. Note that the memory circuit is formed on the second semiconductor die.

In Patent Document 1, the digital pixel stores, in the memory circuit, a code supplied for each column in accordance with the output of the first portion of the comparator, and reads out and outputs the code stored in the memory circuit in response to a read signal.

Therefore, since readout from the pixels is performed row-sequentially, it can be said that this is not suitable for the rolling shutter method in which faster readout is required.

The present disclosure provides an imaging device that is compatible with a rolling shutter method and capable of better noise suppression.

### Solutions to Problems

In order to solve the problems described above, according to an aspect of the present disclosure,
there is provided an imaging device including
a plurality of photoelectric conversion elements that is arranged in a first direction and a second direction intersecting each other, and accumulates electric charges according to a light amount of incident light;
a plurality of pixel circuits that generates an analog pixel signal according to the electric charges accumulated in the plurality of photoelectric conversion elements;
a signal line that transmits the analog pixel signal output from the two or more pixel circuits arranged in the second direction; and
a clip circuit that clips a voltage of the signal line to a predetermined lower limit voltage level using a power supply voltage line of any of the two or more pixel circuits connected to the signal line.

The imaging device may further include
a conversion circuit that performs analog-digital conversion on the analog pixel signal transmitted through the signal line,
in which the conversion circuit may include
a first circuit connected to the signal line, and
a second circuit connected to an output node of the first circuit, and
the first circuit may include the clip circuit.

The conversion circuit may include a current source that generates a current flowing through the signal line, and a current flowing through the clip circuit.

The first circuit may compare the analog pixel signal with a reference signal, and
the second circuit may compare an output signal of the first circuit with a threshold value.

The first circuit may include
a first-stage comparator that compares the analog pixel signal with the reference signal,
the clip circuit may include
a first transistor and a second transistor that are cascode-connected between the power supply voltage line and a reference voltage line of the first-stage comparator,
the first transistor may be turned on when a first signal that instructs clipping to the lower limit voltage level reaches a predetermined level, and
the second transistor may be turned on when a second signal that instructs selection of the first circuit reaches a predetermined level.

The first circuit may include a first input node connected to the power supply voltage line, and a second input node connected to the signal line.

The imaging device may further include
a first semiconductor layer in which the plurality of photoelectric conversion elements and the plurality of pixel circuits are arranged;
a second semiconductor layer that is stacked on the first semiconductor layer and in which the first circuit is arranged;
a first bonding member that bonds the first semiconductor layer and the second semiconductor layer and is connected to the first input node; and
a second bonding member that bonds the first semiconductor layer and the second semiconductor layer and is connected to the second input node.

The signal line may include
a plurality of divided signal lines divided along the second direction,
output nodes of the two or more pixel circuits arranged along the second direction may be respectively connected to the plurality of divided signal lines,
the clip circuit may be provided for each of the plurality of divided signal lines, and may clip, using the power supply voltage line of any of the two or more pixel circuits connected to a corresponding divided signal line, a voltage of the corresponding divided signal line to the predetermined lower limit voltage level, and
the conversion circuit may perform analog-digital conversion on the analog pixel signal transmitted through the plurality of divided signal lines.

The conversion circuit may include
a plurality of the first circuits connected to the plurality of divided signal lines, and
the second circuit connected to output nodes of the plurality of first circuits, and
each of the plurality of first circuits may include the clip circuit.

According to another aspect of the present disclosure, there is provided an imaging device including
a plurality of photoelectric conversion elements that is arranged in a first direction and a second direction intersecting each other, and accumulates electric charges according to a light amount of incident light;
a plurality of pixel circuits that generates an analog pixel signal according to the electric charges accumulated in the plurality of photoelectric conversion elements;
a signal line that transmits the analog pixel signal output from the two or more pixel circuits arranged in the second direction; and
a conversion circuit that performs analog-digital conversion on the analog pixel signal transmitted through the signal line,
in which the signal line includes a plurality of divided signal lines divided along the second direction,
the conversion circuit includes
a plurality of first circuits connected to the plurality of divided signal lines, and
a second circuit connected to output nodes of the plurality of first circuits, and
the output nodes of the plurality of first circuits are divided into two or more sets, and are connected to the second circuit for each of the sets.

The conversion circuit may include a first selector that connects any one set of the two or more sets to the second circuit.

The imaging device may further include
a second selector that selects, for each of the two or more sets, any one of the output nodes of the two or more first circuits belonging to the set, and
the output node of the first circuit selected by the first selector and the second selector may be connected to the second circuit.

The imaging device may further include a precharge circuit that precharges the output node of the first circuit that has not been selected by the second selector.

The imaging device may further include
a first semiconductor layer in which the plurality of photoelectric conversion elements and the plurality of pixel circuits are arranged;
a second semiconductor layer that is stacked on the first semiconductor layer and in which the plurality of first circuits is arranged; and
a third semiconductor layer that is stacked on the second semiconductor layer and in which the second circuit is arranged,
in which the first selector, the second selector, and the precharge circuit may be arranged in the second semiconductor layer.

The imaging device may further include
a first semiconductor layer in which the plurality of photoelectric conversion elements and the plurality of pixel circuits are arranged;
a second semiconductor layer that is stacked on the first semiconductor layer and in which the plurality of first circuits is arranged; and
a third semiconductor layer that is stacked on the second semiconductor layer and in which the second circuit is arranged,
in which each of the first selector, the second selector, and the precharge circuit may be arranged in the second semiconductor layer or the third semiconductor layer.

The imaging device may further include a clip circuit that is provided for each of the plurality of divided signal lines, and clips, using the power supply voltage line of any of the two or more pixel circuits connected to a corresponding divided signal line, a voltage of the corresponding divided signal line to a predetermined lower limit voltage level.

Each of the plurality of first circuits may include a voltage setting circuit that sets a corresponding divided signal line to a predetermined voltage level in a case where the first circuit is not connected to the second circuit.

According to another aspect of the present disclosure, there is provided an imaging device including
a plurality of photoelectric conversion elements that is arranged in a first direction and a second direction intersecting each other, and accumulates electric charges according to a light amount of incident light;
a plurality of pixel circuits that generates an analog pixel signal according to the electric charges accumulated in the plurality of photoelectric conversion elements;
a signal line that transmits the analog pixel signal output from the two or more pixel circuits arranged in the second direction; and
a conversion circuit that performs analog-digital conversion on the analog pixel signal transmitted through the signal line,
in which the signal line includes a plurality of divided signal lines divided along the second direction,
the conversion circuit includes
a plurality of first circuits connected to the plurality of divided signal lines, and
a second circuit connected to output nodes of the plurality of first circuits, and
each of the plurality of first circuits includes a voltage setting circuit that sets a corresponding divided signal line to a predetermined voltage level in a case where the first circuit is not connected to the second circuit.

The voltage setting circuit may include a dummy source follower circuit having a same circuit configuration as circuit configurations of an amplifier transistor and a selection transistor that constitute a source follower circuit in the pixel circuit, and
the dummy source follower circuit may set the corresponding divided signal line to the predetermined voltage level.

### BRIEF DESCRIPTION OF DRAWINGS

FIG. 1 is a block diagram illustrating a configuration of an example of an electronic device Commonly applicable to each embodiment.

FIG. 2 is a block diagram illustrating a configuration of an example of an imaging device in each embodiment of the present disclosure.

FIG. 3 is a schematic diagram schematically illustrating signal processing on a pixel signal by existing technology.

FIG. 4A is a diagram illustrating an example in which the imaging device according to each embodiment is formed using a stacked CIS having a two-layer structure.
FIG. 4B is a diagram illustrating an example in which the imaging device according to each embodiment is formed using a stacked CIS having a three-layer structure.

FIG. 5 is a schematic diagram illustrating a structure of an example of the imaging device according to the embodiment.

FIG. 6 is a schematic diagram schematically illustrating signal processing on a pixel signal according to each embodiment.

FIG. 7 is a schematic diagram illustrating an example in which a pixel array section is divided into a plurality of regions in a vertical direction.

FIG. 8 is a schematic diagram schematically illustrating signal processing on a pixel signal according to a fourth embodiment.

FIG. 9 is a schematic diagram for describing division of a VSL according to the fourth embodiment.

FIG. 10 is a circuit diagram around a first-stage comparator of the imaging device according to a first embodiment.

FIG. 11 is a diagram illustrating an operation of a clip circuit.

FIG. 12 is a diagram illustrating a voltage waveform of a divided VSL in a case of clipping the divided VSL.

FIG. 13 is a diagram illustrating how a voltage level of a power supply voltage line of a pixel circuit fluctuates due to pixel variation.

FIG. 14 is a circuit diagram around a clip circuit according to one comparative example.

FIG. 15 is a diagram illustrating a configuration of a pixel array section according to one comparative example.

FIG. 16 is a diagram illustrating a voltage waveform of a vertical signal line in a case of clipping the vertical signal line.

FIG. 17 is a diagram illustrating how a voltage level of a power supply voltage line of a pixel circuit. fluctuates due to pixel variation.

FIG. 18 is a circuit diagram around a first-stage comparator of an imaging device according to a first modification example of the first embodiment.

FIG. 19 is a circuit diagram around a first-stage comparator of an imaging device according to a second modification example of the first embodiment.

FIG. 20 is a circuit diagram around a first-stage comparator of an imaging device according to a third modification example of the first embodiment.

FIG. 21 is a block diagram illustrating a schematic configuration of a comparator according to the first embodiment.

FIG. 22 is a block diagram illustrating a schematic configuration of a comparator according to a second embodiment.

FIG. 23 is a block diagram illustrating a schematic configuration of a comparator according to a first modification example of the second embodiment.

FIG. 24 is a block diagram illustrating a schematic configuration of a comparator according to a second modification example of the second embodiment.

FIG. 25 is a circuit diagram around a first-stage comparator of the imaging device according to the second embodiment.

FIG. 26 is a circuit diagram around a first-stage comparator of an imaging device according to a modification example of the second embodiment.

FIG. 27 is a circuit diagram around a first-stage comparator of an imaging device according to a third embodiment.

FIG. 28 is a diagram illustrating a voltage waveform of the divided VSL illustrated in FIG. 27 and a current waveform flowing through the power supply voltage line of the pixel circuit.

FIG. 29 is a circuit diagram around a first-stage comparator of the imaging device according to one comparative example.

FIG. 30 is a diagram illustrating a voltage waveform of the divided VSL illustrated in FIG. 29 and a current waveform flowing through the power supply voltage line of the pixel circuit.

FIG. 31 is a circuit diagram around the first-stage Comparator of the imaging device having characteristic functions according to the first to third embodiments.

FIG. 32A is a schematic diagram illustrating a sectional structure of an example of an imaging device according to a first example of the fourth embodiment.

FIG. 32B is a schematic diagram illustrating a sectional structure of an example of the imaging device according to the first example of the fourth embodiment.

FIG. 33 is a block diagram illustrating an example of a schematic configuration of a vehicle control system.

FIG. 34 is an explanatory diagram illustrating an example of installation positions of an outside-vehicle information detecting section and an imaging section.

### MODE FOR CARRYING OUT THE INVENTION

Hereinafter, embodiments of an imaging device will be described with reference to the drawings. Although main components of the imaging device will be mainly described below, the imaging device may have components and functions that are not illustrated or described. The following description does not exclude the components and functions that are not illustrated or described.

### Electronic Device Commonly Applicable to Each Embodiment

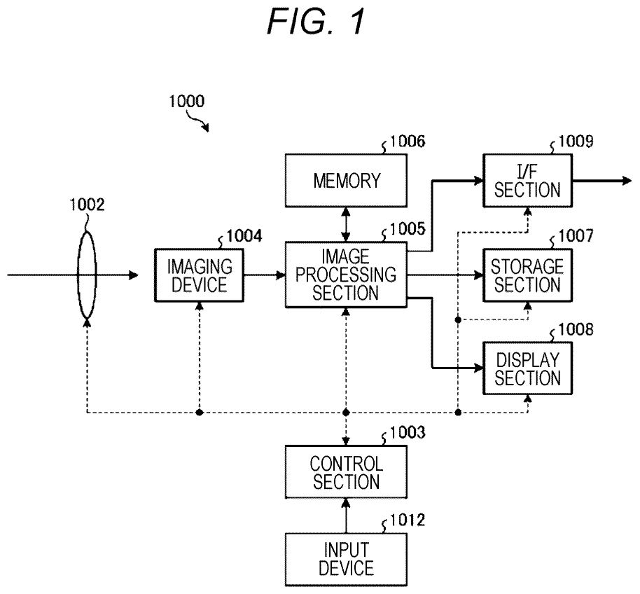

FIG. 1 is a block diagram illustrating a configuration of an example of an electronic device commonly applicable to each embodiment. In FIG. 1, an electronic device 1000 includes an optical system 1002, a control section 1003, an imaging device 1004, an image processing section 1005, a memory 1006, a storage section 1007, a display section 1008, an interface (I/F) section 1009, and an input device 1012. Here, examples of the electronic device 1000 include a digital still camera, a digital video camera, and a mobile phone or smartphone with an imaging function. Furthermore, a surveillance camera, an in-vehicle camera, or a medical camera may also be used as the electronic device 1000.

The imaging device 1004 includes, for example, a plurality of photoelectric conversion elements arranged in a matrix array. The photoelectric conversion element converts received light into electric charge through photoelectric conversion. The imaging device 1004 includes a drive circuit that drives the plurality of photoelectric conversion elements, a signal processing circuit that reads out electric charges from each of the plurality of photoelectric conversion elements and generates image data on the basis of the read-out electric charges, and a power supply circuit that supplies power to the drive circuit.

The optical system 1002 includes a main lens including one or a plurality of lenses in combination, and a mechanism for driving the main lens, and forms an image of subject light (incident light) from a subject on a light receiving surface of the imaging device 1004 through the main lens. Furthermore, the optical system 1002 also includes an autofocus mechanism that adjusts focus in accordance with a control signal, and a zoom mechanism that changes a zoom ratio in accordance with the control signal. Furthermore, the electronic device 1000 may allow the optical system 1002 to be attachable and detachable so that the optical system 1002 can be replaced with another optical system 1002.

The image processing section 1005 executes predetermined image processing on the pixel data output from the imaging device 1004. For example, the image processing section 1005 is connected to the memory 1006 such as a frame memory, and writes the image data output from the imaging device 1004, into the memory 1006. The image processing section 1005 executes predetermined image processing on the pixel data written into the memory 1006 and writes the pixel data subjected to the image processing, into the memory 1006 again. Note that the memory 1006 can store one frame of pixel data as image data.

The storage section 1007 is, for example, a non-volatile memory such as a flash memory or a hard disk drive, and stores the image data output from the image processing section 1005 in a non-volatile manner. The display section 1008 includes, for example, a display device such as a liquid crystal display (LCD) and a drive circuit that drives the display device, and can display an image based on the image data output by the image processing section 1005. The I/F section 1009 is an interface for transmitting the image data output from the image processing section 1005, to the outside. For example, a Universal Serial Bus (USB) can be used as the I/F section 1009. The present invention is not limited thereto, and the I/F section 1009 may be an interface connectable to a network through wired communication or wireless communication.

The input device 1012 includes an operator or the like for receiving a user's input. In a case where the electronic device 1000 is, for example, a digital still camera, a digital video camera, or a mobile phone or smartphone with an imaging function, the input device 1012 may include a shutter button for instructing the imaging by the imaging device 1004, or an operator for implementing the function of the shutter button.

The control section 1003 includes, for example, a processor such as a Central Processing Unit (CPU), a Read Only Memory (ROM), and a Random Access Memory (RAM), and controls the overall operation of the electronic device 1000 by using the RAM as a work memory in accordance with a program stored in the ROM in advance. For example, the control section 1003 can control the operation of the electronic device 1000 according to the user's input received through the input device 1012. Furthermore, the control section 1003 can control the autofocus mechanism in the optical system 1002 on the basis of an image processing result of the image processing section 1005.

### Imaging Device Commonly Applicable to Each Embodiment

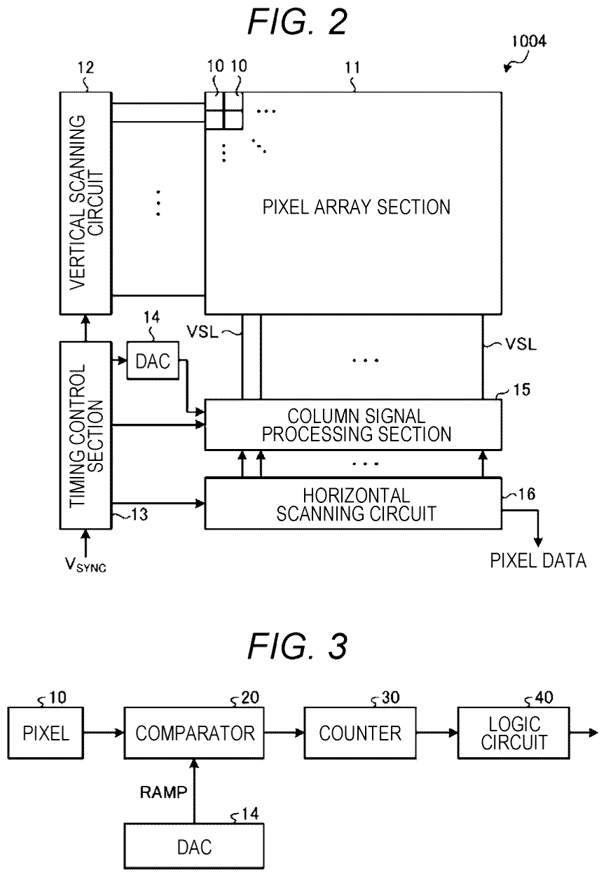

FIG. 2 is a block diagram illustrating a configuration example of the imaging device 1004 according to each embodiment of the present disclosure.

In FIG. 2, the imaging device 1004 includes a vertical scanning circuit 12, a timing control section 13, a Digital to Analog Converter (DAC) 14, a pixel array section 11, a column signal processing section 15, and a horizontal scanning circuit 16. The imaging device 1004 can be configured as a Complementary Metal Oxide Semiconductor (CMOS) image sensor (CIS) in which these components are integrally formed using the CMOS.

In the pixel array section 11, a plurality of pixels 10 is arranged in a matrix array. Hereinafter, in the pixel array section 11, a horizontal direction in FIG. 2 is defined as the row, and the vertical direction is defined as the column.

In the pixel array section 11, each pixel 10 includes a photoelectric conversion element that generates electric charge in response to received light, and a pixel circuit that outputs a pixel signal on the basis of the electric charge generated by the photoelectric conversion element. The vertical scanning circuit 12 drives each pixel 10 included in the pixel array section 11 on a per-row basis to output a pixel signal from each pixel 10. At this time, the vertical scanning circuit 12 sequentially drives each pixel 10 in the order of rows to output the pixel signal. That is, the vertical scanning circuit 12 functions as a readout control circuit that controls the reading out of electric charge from the photoelectric conversion elements and the output of the pixel signals.

The timing control section 13 controls the operation timing of each of the vertical scanning circuit 12, the DAC 14, the column signal processing section 15, and the horizontal scanning circuit 16 in synchronization with a vertical synchronization signal VSYNC. The vertical synchronization signal VSYNC is a periodic signal having a predetermined frequency (for example, 60 hertz (Hz) ) that indicates the imaging timing.

The DAC 14 generates a predetermined reference signal by Digital to Analog (DA) conversion. As the reference signal, for example, a sawtooth-shaped ramp (RAMP) signal is used. The DAC 14 supplies the reference signal to the column signal processing section 15.

The column signal processing section 15 receives analog pixel signals output from the pixels 10 through a vertical signal line VSL provided for each column in the pixel array section 11. The column signal processing section 15 performs signal processing, such as Analog to Digital (AD) conversion processing and Correlated Double Sampling (CDS) processing, on the pixel signals on a per-column basis. The column signal processing section 15 outputs the processed digital pixel signals (pixel data). The pixel data output from the column signal processing section 15 is supplied to the image processing section 1005.

The horizontal scanning circuit 16 controls the column signal processing section 15 to output the pixel data from the column signal processing section 15 on a per-row basis in order in the column direction, for example.

### Flow of Processing by Existing Technology

Next, signal processing on the pixel signal by the existing technology will be schematically described. FIG. 3 is a schematic diagram schematically illustrating the signal processing on the pixel signal by the existing technology. In FIG. 3, a comparator 20, a counter 30, and a logic circuit 40 are included in, for example, the column signal processing section 15 in FIG. 2.

The analog pixel signal output from the pixel 10 is supplied to the comparator 20. Moreover, the RAMP signal as a reference signal is supplied from the DAC 14 to the comparator 20. The RAMP signal is, for example, a signal in which a level (voltage value) is gradually decreased over time, for example, in accordance with predetermined clock pulses. The comparator 20 compares the pixel signal with the RAMP signal, and supplies a comparison result to the counter 30. For example, in a case where the level of the RAMP signal is higher than the level of the pixel signal, the comparator 20 outputs a high-level difference signal to the counter 30. On the other hand, in a case where the level of the RAMP signal becomes the Same as or equal to or lower than the level of the pixel signal, the comparator 20 inverts its output and outputs a low-level difference signal to the counter 30.

The counter 30 counts, during each of a P phase (Preset Phase) period and a D phase (Data Phase) period, the time from when the ramp signal RAMP starts to drop in voltage until the level of the ramp signal RAMP becomes the same as or equal to or lower than the level of the pixel signal, in accordance with the difference signal input from the comparator 20, and outputs the respective count results to the logic circuit 40. Note that the P phase period is a period for detecting a reset level of the pixel signal in CDS processing, and the D phase period is a detection period for detecting the signal level of the pixel signal in CDS processing.

The logic circuit 40 performs CDS processing and AD conversion processing on the basis of the count result of the P phase period and the count result of the D phase period that are input from the counter 30, and generates and outputs the digital pixel signal (pixel data).

### Structure of Imaging Device Applicable to Each Embodiment

Next, the structure of the imaging device applicable to each embodiment will be schematically described. The imaging device 1004 according to the embodiment can be formed with a stacked structure in which a plurality of layers of semiconductor chips are stacked.

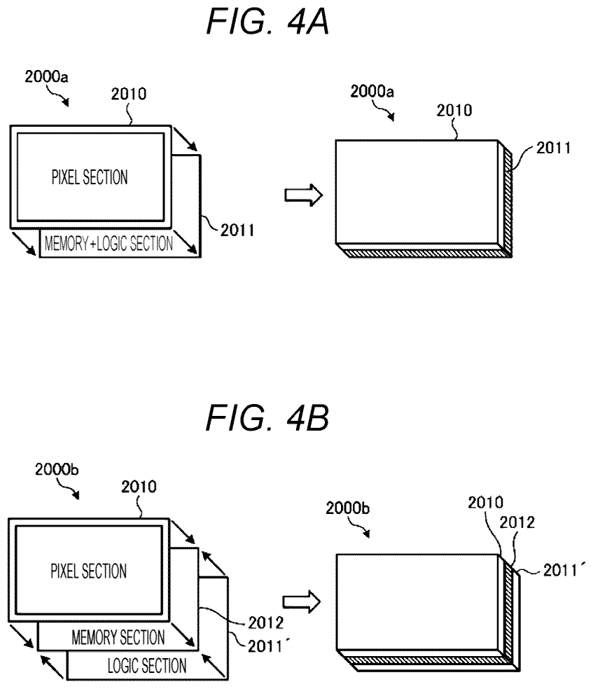

As an example, the imaging device 1004 can be formed with a two-layer structure in which semiconductor chips are stacked in two layers. FIG. 4A is a diagram illustrating an example in which the imaging device 1004 according to each embodiment is formed using a stacked CIS having a two-layer structure. In the structure of FIG. 4A, a pixel section 2010 is formed on the first-layer semiconductor chip, and a memory+logic section 2011 is formed on the second-layer semiconductor chip.

The pixel section 2010 includes at least the pixel array section 11. The memory+logic section 2011 may include, for example, the vertical scanning circuit 12, the timing control section 13, the DAC 14, the column signal processing section 15, the horizontal scanning circuit 16, and an interface for communication between the imaging device 1004 and an external device. Furthermore, the memory+logic section 2011 may also include, for example, a memory for storing pixel data output from the column signal processing section 15.

As illustrated on the right side of FIG. 4A, the imaging device 1004 is configured as one solid-state imaging element 2000a by bonding the first-layer semiconductor chip and the second-layer semiconductor chip while electrically contacting each other.

As another example, the imaging device 1004 can be formed with a three-layer structure in which semiconductor chips are stacked in three layers. FIG. 4B is a diagram illustrating an example in which the imaging device 1004 according to each embodiment is formed using a stacked CIS having a three-layer structure. In the structure of FIG. 4B, the pixel section 2010 is formed on the first-layer semiconductor chip, a memory section 2012 is formed on the second-layer semiconductor chip, and a logic section 2011′ is formed on the third-layer semiconductor chip. In this case, the logic section 2011′ may include, for example, the vertical scanning circuit 12, the timing control section 13, the DAC 14, the column signal processing section 15, the horizontal scanning circuit 16, and an interface for communication between the imaging device 1004 and an external device. Furthermore, the memory section 2012 may also include, for example, a memory for storing pixel data output from the column signal processing section 15.

As illustrated on the right side of FIG. 4B, the imaging device 1004 is configured as one solid-state imaging element 2000b by bonding the first-layer semiconductor chip, the second-layer semiconductor chip, and the third-layer semiconductor chip while electrically contacting each other.

### Configuration According to Each Embodiment

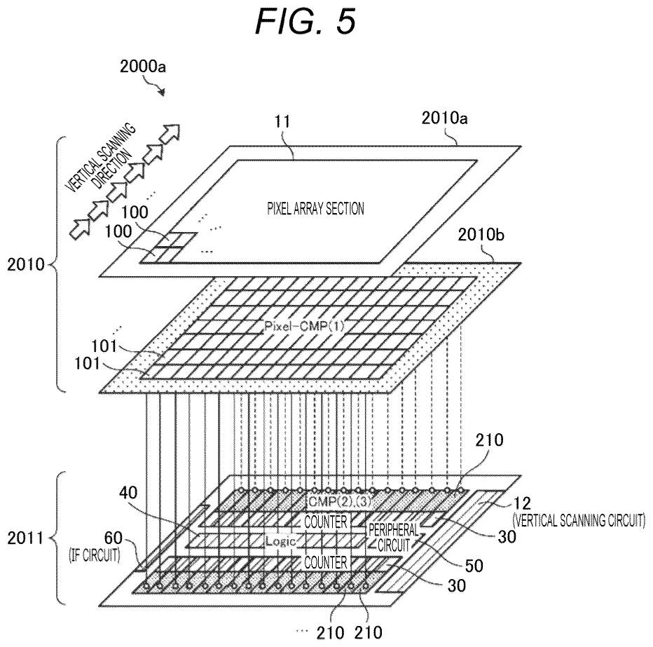

Next, the configuration of each embodiment will be described. FIG. 5 is a schematic diagram illustrating a structure of an example of the imaging device 1004 according to the embodiment. In the example of FIG. 5, the imaging device 1004 employs the solid-state imaging element 2000a having the two-layer structure, described with reference to FIG. 4A. Here, in the case of a back-illuminated image sensor, the photoelectric conversion elements are formed on a first layer 2010a of the substrate, and the pixel circuits that convert the electric charge generated by the photoelectric conversion elements into pixel signals and output the pixel signals are formed on a second layer 2010b of the substrate. The first layer 2010a and the second layer 2010b constitute the pixel section 2010.

In FIG. 5, photoelectric conversion sections 100, each of which includes a photoelectric conversion element. and a transistor for controlling the readout of electric charge from the photoelectric conversion element, are arranged in a matrix array on the first layer 2010a. Circuit sections 101, each of which includes a pixel circuit that converts the electric charge read out from the photoelectric conversion section 100 into the pixel signal, are arranged in a matrix array on the second layer 2010b to correspond to the photoelectric conversion sections 100 on the first layer 2010a. More specifically, the circuit section 101 is arranged in a one-to-one relationship with the photoelectric conversion section 100 located on the first layer 2010a, while being electrically connected between the first layer 2010a and the second layer 2010b.

In each embodiment, moreover, the circuit section 101 (denoted as Pixel-CMP (1) in the drawing) includes a part of the comparator 20. That is, in each embodiment, the comparator 20 is configured by being divided into at least two parts of a first circuit (denoted as CMP (1)) to which the pixel signal is directly supplied from the pixel circuit, and second and third circuits (denoted as CMP (2) and CMP (3)) to which the output of the first circuit is supplied. The first circuit includes, for example, a circuit that compares the pixel signal output from the pixel circuit with the RAMP signal supplied from the DAC 14.

In FIG. 5, the memory+logic section 2011 is provided with the vertical scanning circuit 12, the counter 30, the logic circuit 40, a peripheral circuit 50, and an interface circuit 60 (also referred to as the IF circuit in the drawing).

The peripheral circuit 50 includes the DAC 14. Furthermore, the interface circuit 60 is an interface for transmitting and receiving signals between the imaging device 1004 as the solid-state imaging element 2000a and the outside.

In the example of FIG. 5, the vertical scanning circuit 12 is arranged along the column direction of the pixel array section 11 at one end (the right end in the illustrated example) in the row direction of the memory+logic section 2011. Furthermore, the interface circuit 60 is arranged along the column direction of the pixel array section 11 at the other end (the left end in the illustrated example) in the row direction of the memory+logic section 2011.

Furthermore, the memory+logic section 2011 is provided with a second circuit 210 obtained by dividing the comparator 20. In the example of FIG. 5, the second circuit 210 is arranged along the row direction of the memory+logic section 2011 at one end and the other end (the upper and lower ends in the example of FIG. 5) in the column direction. The second circuit 210 is provided for each column in the pixel array section 11. In the example of FIG. 5, the second circuit 210 is provided along the row direction of the pixel array section 11 at. both ends in the column direction of the memory+logic section 2011.

The second circuit 210 is shared by a plurality of circuit sections 101 arranged along the columns in the second layer 2010b. For example, each second circuit 210 arranged at one end (for example, the upper end in the drawing) in the column direction of the memory+logic section 2011 is shared, for each column, by the circuit sections 101 arranged on the one-end-side half (the upper-side half in the example of FIG. 5) among the circuit sections 101 arranged in the second layer 2010b. Similarly, each second circuit 210 arranged at the other end (for example, the lower end in FIG. 5) in the column direction of the memory+logic section 2011 is shared, for each column, by the circuit sections 101 arranged on the other-end-side half (the lower-side half in the example of FIG. 5) among the circuit sections 101 arranged in the second layer 2010b.

Note that each pixel 10 (each photoelectric conversion section 100 and each circuit section 101) is scanned in the column direction, that is, in the vertical direction, as indicated by the arrows. The output from each pixel 10 (each circuit section 101) is transferred to the memory+logic section 2011 on a per-row basis.

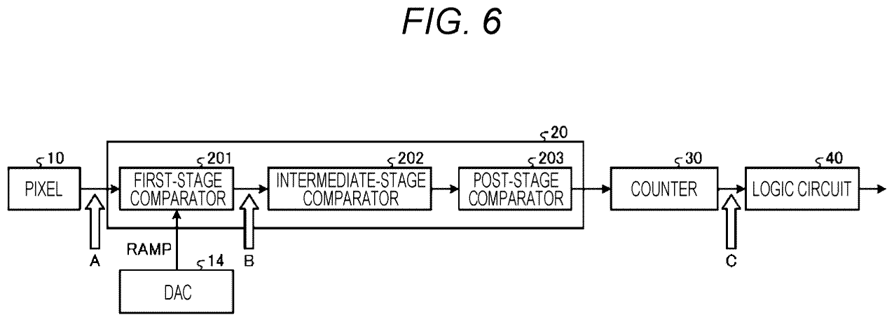

FIG. 6 is a schematic diagram schematically illustrating signal processing on the pixel signal according to each embodiment. In each embodiment of the present disclosure, the comparator 20 is divided into a plurality of circuits. In the example of FIG. 6, the Comparator 20 is divided into three circuits of a first-stage comparator 201, an intermediate-stage comparator 202, and a post-stage comparator 203. The first-stage comparator 201 corresponds to the first circuit described with reference to FIG. 5, and includes, for example, a circuit that compares the pixel signal output from the pixel 10 with the RAMP signal supplied from the DAC 14. The intermediate-stage comparator 202 and the post-stage comparator 203 correspond to the second circuit described with reference to FIG. 5, and compare the output of the first circuit with a threshold value. The intermediate-stage comparator 202 and the post-stage comparator 203 may also be configured as a single circuit.

### Example of Dividing Pixel Array Section into Regions

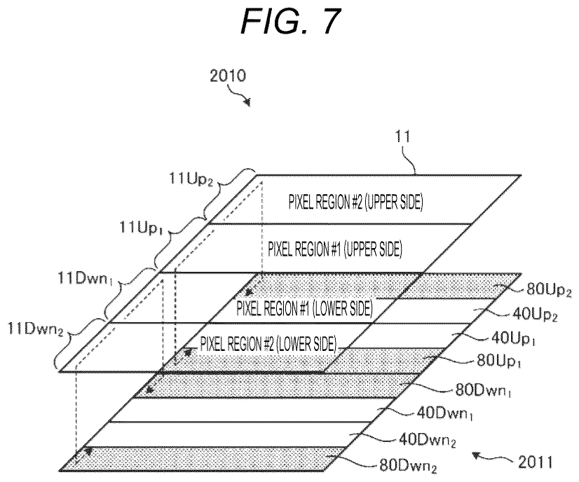

By dividing the pixel array section 11 into a plurality of regions in the vertical direction and transferring the pixel signal for each divided region, it is possible to shorten the distance over which the pixel signal is transferred. FIG. 7 is a schematic diagram illustrating an example in which the pixel array section 11 is divided into a plurality of regions in the vertical direction.

In the example of FIG. 7, in the pixel section 2010, the pixel array section 11 is divided in the vertical direction into four regions of pixel regions 11Up₁ and 11Up₂, and pixel regions 11Dwn₁ and 11Dwn₂.

Among the pixel regions, the pixel regions 11Up₁ and 11Up₂ are respectively first and second pixel regions on the upper side, and the pixel regions 11Dwm₁ and 11Dwn₂ are respectively first and second pixel regions on the lower side.

In the memory+logic section 2011, an analog circuit 80Up₁ and a logic circuit 40Up₁ are arranged at positions corresponding to the pixel region 110ₚ₁, and an analog circuit 80Up₂ and a logic circuit 40Up₂ are arranged at positions corresponding to the pixel region 11Up₂. Similarly, an analog circuit 80Dwn₁ and a logic circuit 40Dwn₁ are arranged at positions corresponding to the pixel region 11Dwn₁, and an analog circuit 80Up₂ and a logic circuit 40Dwn₂ are arranged at positions corresponding to the pixel region 11Up₂.

Note that each of the analog circuits 80Up₁, 80Up₂, 80Dwn₁, and 80Dwn₂ includes, for example, the pixel circuit, the comparator 20, and the counter 30.

The pixel signal output from each pixel in the pixel region 11Up₁ is transferred, on a per-row basis, through the vertical signal line within the pixel region 11Up₁, from the end portion of the pixel region 11Up₁ to the memory+logic section 2011, and is input to the analog circuit 80Up₁. The output of the analog circuit 80Up₁ is input to the logic circuit 40Up₁. The similar processing applies to the pixel regions 11Up₂, 11Dwn₁, and 11Dwn₂.

With the configuration of FIG. 7, the pixel signal output from each pixel is transferred over a distance of at most one-fourth the distance between both ends in the column direction of the pixel array section 11. However, the fact that the pixel signal is transferred through the vertical signal line is not changed from the existing configuration. Therefore, the parasitic capacitance of the shortened vertical signal lines affects only the settling in each pixel 10 and is unlikely to lead to improvements in characteristics such as noise reduction.

On the other hand, in each embodiment of the present disclosure, since the distance over which the electric charge generated in the pixel 10 is transferred to the first-stage comparator 201 is made extremely short, the settling time in the pixel 10 can be shortened, and with this arrangement, the readout time of the electric charge from the pixel 10 can be increased in speed. Furthermore, since the vertical signal line, which becomes a large load, is connected to the output side of the first-stage comparator 201, the bandwidth of the signal transferred to the vertical signal line can be narrowed, and noise can be reduced.

In the above, the VSL is divided in the vertical direction to reduce the load of the VSL. However, even in a case where the number of divisions of the VSL is increased, routing wiring to the input terminal of the ADC provided in the column signal processing section 15 is required, and thus it is difficult to increase the processing speed and achieve a high frame rate. For example, in a two-layer stacked structure, the number of divisions of the VSL is generally limited to about two. Furthermore, since one ADC corresponds to a plurality of pixels, the load at a pixel switching portion becomes heavy.

Therefore, in the imaging device according to the present disclosure, one first-stage comparator 201 is provided for each divided region of the VSL in the intermediate layer (the second layer of the first substrate) in the three-layer configuration including the first layer and second layer of the first substrate and the second substrate, and the output of the first-stage comparator 201 is switched by a select switch and input to the intermediate-stage comparator 202. By adopting such a configuration, the VSL load is reduced by the increase in the number of divisions of the VSL, and it is possible to increase the processing speed and achieve a high frame rate.

Furthermore, in the imaging device according to the present disclosure, a plurality of pixels (photoelectric conversion sections 100) is connected to a single first-stage comparator 201. That is, the imaging device is configured to switch connections at two points: between the pixel and the first-stage comparator 201, and between the first-stage comparator 201 and the intermediate-stage comparator 202. Therefore, the load at the pixel switching portion (that is, the VSL wiring) can be reduced.

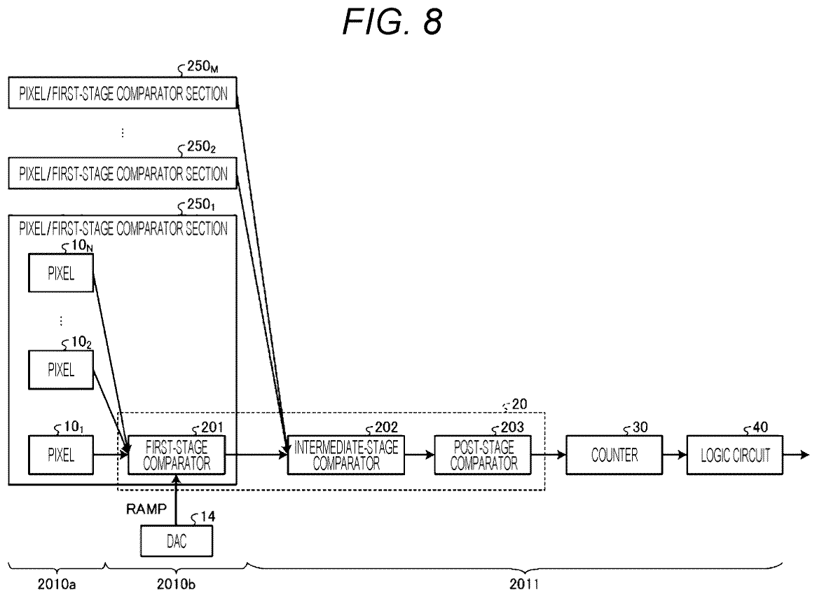

FIG. 8 is a schematic diagram schematically illustrating signal processing on the pixel signal according to the imaging device according to the present disclosure.

Similar to FIG. 6 described above, in FIG. 8, the comparator 20 includes the first-stage comparator 201, the intermediate-stage comparator 202, and the post-stage Comparator 203, and the output of the post-stage Comparator 203 is input to the counter 30, and the output of the counter 30 is input to the logic circuit 40.

Furthermore, the RAMP signal output from the DAC 14 is supplied to the first-stage comparator 201.

In the configuration illustrated in FIG. 8, pixel signals from N (N≥1) pixels 10₁, 10₂, . . . , and 10_{N} are input to the first-stage comparator 201. The outputs of M (M≥2) pixel/first-stage comparator sections 250₁, 250₂, and 250M each including the first-stage comparator 201 and the pixels 10₁, 10₂, . . . and 10_{N} are input to the intermediate-stage comparator 202.

Furthermore, among these, the respective pixels 10₁, 10₂, 10_{N} included in the pixel/first-stage comparator sections 250₁, 250₂, . . . , 250_{M} are arranged on the first layer 2010a of the pixel section 2010, and the respective first-stage comparators 201 are arranged on the second layer 2010b of the pixel section 2010. The configurations from the intermediate-stage comparator 202 onward are arranged in the memory+logic section 2011.

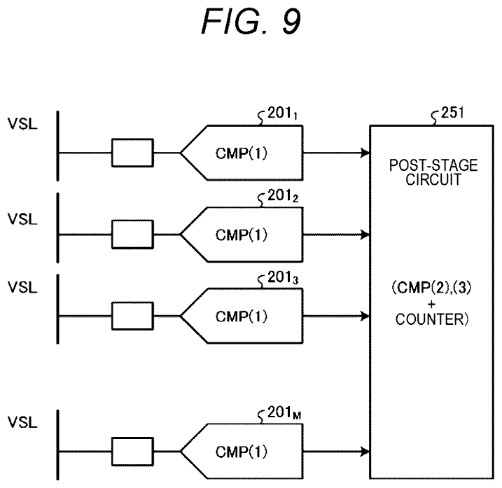

FIG. 9 is a schematic diagram for describing the division of the VSL according to the imaging device according to the present disclosure. Note that, in FIG. 9, first-stage comparators 201₁ to 201M are also illustrated as the first circuit CMP(1). Furthermore, a post-stage circuit 251 includes the intermediate-stage comparator 202, the post-stage comparator 203 (second and third circuits CMP(2) and CMP(3)), and the counter 30.

As illustrated in FIG. 9, the VSL connects each of the pixels 10₁ to 10x with the corresponding first-stage comparators 201₁ to 201x in each of the pixel/first-stage comparator sections 250₁, 250₂, . . . , and 250_{M}. That is, in the imaging device according to the present disclosure, the VSL is divided for each first-stage comparators 201₁ to 201_{M}.

As described above, in the imaging device according to the present disclosure, the signal paths are switched both between each of the pixels 101 to 10w and the first-stage comparator 201, and between each of the pixel/first-stage comparator sections 2501 to 250%.

Therefore, the VSL is divided for each of the first-stage comparators 2011 to 201, and the load on the VSL wiring is reduced.

### First Embodiment

A semiconductor chip such as the imaging device 1004 is required to be driven at a low voltage. When the imaging device 1004 is driven at a low voltage, the signal amplitude on the vertical signal line VSL becomes smaller, and there is element variation for each pixel. Therefore, it is difficult to design a current source that supplies current to the vertical signal line VSL.

For example, a lower limit voltage of the vertical signal line VSL depends on the signal amplitude of the vertical signal line VSL, the electrical characteristics of the pixel transistor, the potential of the FD, the element variation in the photoelectric conversion element, and the like, and a design margin (also referred to as headroom) allowable for the current source described above becomes more stringent. The imaging device 1004 according to the first embodiment described below is intended to solve the above-described problems.

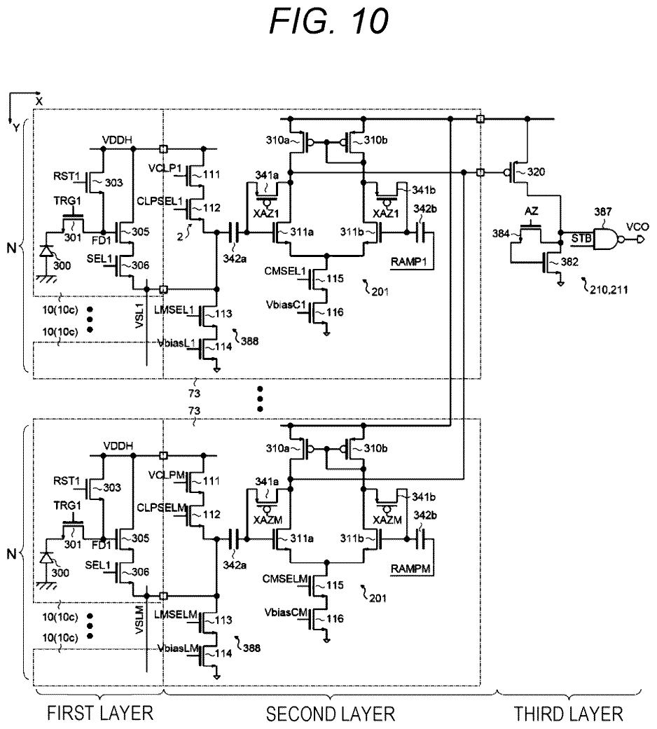

FIG. 10 is a circuit diagram around the first-stage comparator 201 of the imaging device 1004 according to the first embodiment. The imaging device 1004 illustrated in FIG. 10 illustrates an example of a three-layer structure. A pixel circuit 10c is arranged on the first layer 2010a. A first circuit 73 of the comparator 20 is arranged on the second layer 2010b stacked below the first layer 2010a. The second circuit 210 and a third circuit 211 of the comparator 20 are arranged on a third layer 2010c stacked below the second layer 2010b.

Similar to FIG. 9, in the example of FIG. 10, the vertical signal line VSL is divided into a plurality of sections along the vertical direction (second direction). Hereinafter, each of the divided vertical signal lines VSL may be referred to as a divided VSL.

Two or more pixel circuits 10c arranged in the vertical direction (second direction) are connected to each divided VSL. Furthermore, the first circuit 73 in one comparator 20 is connected to each divided VSL.

The comparator 20 includes a plurality of first circuits 73, one second circuit 210, and one third circuit 211. The first circuit 73 includes the first-stage comparator 201, the second circuit 210 includes the intermediate-stage comparator 202, and the third circuit 211 includes the post-stage comparator 203.

More specifically, the first circuit 73 includes a clip circuit 2, the first-stage comparator 201, and a current source. As described later, the current source may be arranged in the second circuit 210.

The clip circuit 2 clips the voltage of the divided VSL to a predetermined lower limit voltage level using a power supply voltage line VDDH of one of the two or more pixel circuits 10c connected to the divided VSL. By providing the clip circuit 2, the voltage level of the divided VSL does not fall below the predetermined lower limit voltage level, and thus the settling time of the divided VSL can be shortened. The clip circuit 2 is provided for each of the plurality of divided VSLs, and clips the voltage of the corresponding divided VSL to the predetermined lower limit voltage level using the power supply voltage line VDDH of one of the two or more pixel circuits connected to the corresponding divided VSL.

The clip circuit 2 includes two NMOS transistors 111 and 112 that are cascode-connected between the power supply voltage line VDDH of the pixel circuit 10c connected to the divided VSL and a power supply line of the first circuit 73. A VCLP signal is input to the gate of the MOS transistor 111, and a CLPSEL signal is input to the gate of the NMOS transistor 112. In FIG. 10, suffixes are added to VCLP and CLPSEL, but the suffixes are omitted in this specification. The VCLP signal is a signal that specifies a clip voltage of the divided VSL. When the clip voltage of the divided VSL is specified, the VCLP signal is set to an analog voltage that specifies the lower limit voltage of the divided VSL. The CLPSEL signal goes to a high level when selecting a specific divided VSL to be set to the lower limit voltage level. The CLPSEL signal is provided separately for each clip circuit 2.

When both the VCLP signal and the CLPSEL signal go to a high level, both the transistors 111 and 112 are turned on, and a current flows to the clip circuit 2 from the power supply voltage line VDDH of the pixel circuit 10c connected to the divided VSL.

As illustrated in FIG. 10, the output node of the clip circuit 2 is connected to the input node of the first-stage comparator 201 and a current source 388. In a case where the two transistors 111 and 112 in the clip circuit 2 are turned on together, a current flows from the power supply voltage line VDDH of the pixel circuit 10c connected to the divided VSL to the current source 388 through the clip circuit 2, and the divided VSL is clipped to a predetermined lower limit voltage level defined by the transistor 111. Furthermore, in a case where at least one transistor in the clip circuit 2 is turned off, the current from the power supply voltage line VDDH does not flow to the clip circuit 2, and thus the divided VSL is not clipped.

The first-stage comparator 201 included in the first circuit 73 in FIG. 10 is configured as a differential comparator that includes an active load formed by PMOS transistors 310a and 310b, and a differential pair formed by NMOS transistors 311a and 311b. In the first-stage comparator 201, the RAMP signal is supplied to the gate of the NMOS transistor 311b through a capacitor 342b. Furthermore, the gate of the NMOS transistor 311a is connected to a divided VSL1 through a capacitor 342a and also connected to the current source 388, and receives the pixel signal output from the pixel circuit 10c.

Furthermore, in the first-stage comparator 201, the drain and source of a PMOS transistor 341a are connected to the drain and gate of the NMOS transistor 311a, respectively. Similarly, the drain and source of a PMOS transistor 341b are connected to the drain and gate of the NMOS transistor 311b, respectively. The PMOS transistors 341a and 341b are provided to perform an auto-zero operation in accordance with a signal XAZ1.

Note that each of signals TRG, RST, SEL, CMSEL, and AZ (suffixes are omitted) is generated in the logic circuit 40 of the memory +logic section 2011, and supplied to the first-stage comparator 201 through the vertical scanning circuit 12.

The second circuit 210 includes NMOS transistors 320, 382, and 384, and a NAND circuit 387. The source of the NMOS transistor 320 is connected to the power supply line, and the drain thereof is connected to the drain of each of the NMOS transistors 382 and 384, as well as to one input node of the NAND circuit 387. The gate of the NMOS transistor 320 is connected to the output node of the first circuit 73. The source of the NMOS transistor 382 is grounded, and the gate thereof is connected to the source of the NMOS transistor 384. A binary signal VCO indicating the comparison result is output from the NAND circuit 387.

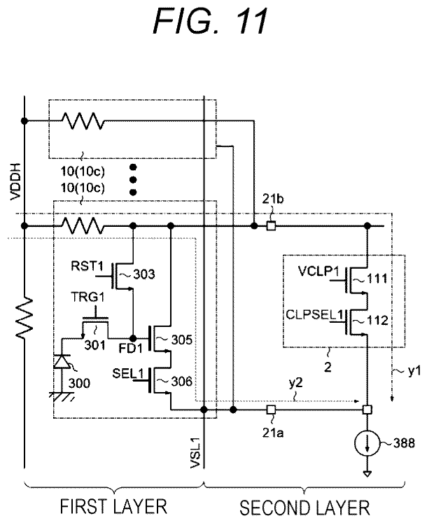

FIG. 11 is a diagram illustrating an operation of the clip circuit 2. As illustrated in FIG. 11, two or more pixel circuits 10c are connected to the divided VSL (VSL1 in FIG. 11), and the clip circuit 2 in the first circuit 73 is connected thereto.

As illustrated in FIG. 11, while the pixel circuit 10c is arranged on the first layer 2010a, the first circuit 73 including the clip circuit 2 is arranged on the second layer 2010b. The first layer 2010a and the second layer 2010b are joined, for example, by Copper-Copper Connections (CCCs) 21a and 21b to perform signal transmission. The first layer 2010a and the second layer 2010b have two CCCs for each divided VSL. One CCC 21a is used to supply the pixel signal, which is output from two or more pixel circuits 10c connected to the divided VSL, to the first circuit 73 of the second layer 2010b. The other CCC 21b is used to supply the power supply voltage line VDDH of any pixel circuit 10c among the two or more pixel circuits 10c connected to the divided VSL, to the clip circuit 2 of the second layer 2010b.

In a case where the two transistors 111 and 112 in the clip circuit 2 are turned on, a current flows (indicated by an arrow line y1) from the power supply voltage line VDDH of the pixel circuit 10c connected to the divided VSL to the current source 388 through the clip circuit 2, and the divided VSL is clipped to a predetermined lower limit voltage level.

When at least one of the two transistors 111 and 112 in the clip circuit 2 is turned off, the current from the power supply voltage line VDDH does not flow to the clip circuit 2. In this case, the pixel signal output from any pixel circuit 10c among the two or more pixel circuits 10c connected to the divided VSL is input to the first circuit 73 through the divided VSL and one CCC 21a, and the current flows from the output node of the pixel circuit 10c to the current source 388 (indicated by an arrow line y2).

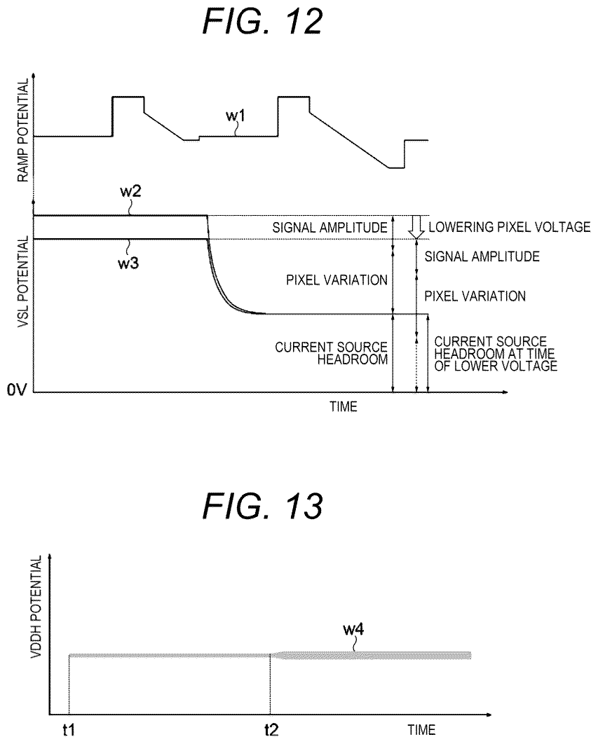

FIG. 12 is a diagram illustrating a voltage waveform of the divided VSL in the case of clipping the divided VSL, in the imaging device 1004 according to the first embodiment. FIG. 12 illustrates a waveform w1 of the reference signal (RAMP signal), a waveform w2 of the divided VSL at the time of the clipping in a case where the power supply voltage of the imaging device 1004 is not lowered, and a waveform w3 of the divided VSL at the time of the clipping in a case where the power supply voltage is lowered.

As illustrated in FIG. 12, by providing the clip circuit 2, the voltage level of the divided VSL at the time of the clipping remains nearly the same in a case where the power supply voltage of the imaging device 1004 is lowered or in a case where the power supply voltage of the imaging device 1004 is not lowered, and it becomes almost unaffected by the pixel variation. Therefore, even in a case where the power supply voltage of the imaging device 1004 is lowered, a sufficient design margin (headroom) for the current source 388 can be ensured, the design cost can be reduced, and the reliability of the current source 388 can be improved.

FIG. 13 is a diagram illustrating how the voltage level of the power supply voltage line VDDH of the pixel circuit 10c fluctuates due to the pixel variation. In FIG. 13, the horizontal axis represents time, and the vertical axis represents a voltage level. In FIG. 13, a period from time t1 to time t2 indicates the voltage level of the power supply voltage line VDDH at the time of the normal pixel signal readout, and a period after time t2 indicates the voltage level of the power supply voltage line VDDH at the time of the clipping. FIG. 13 illustrates a waveform w4 of the power supply voltage line VDDH in a case where the clip circuit 2 according to the first embodiment is used. As illustrated in FIG. 13, at the time of the clipping, the fluctuation in the power supply voltage line VDDH due to the pixel variation becomes slightly larger than that at the time of the pixel signal readout, but the voltage fluctuation is not significant enough to affect the design margin of the current source 388.

As described above, in the present embodiment, since the path through which the current flows to the current source 388 is not changed so much between the time of the readout of the pixel signal and the time of the clipping of the pixel signal, it is possible to reduce the voltage fluctuation due to the pixel variation of the power supply voltage line VDDH at the time of the clipping.

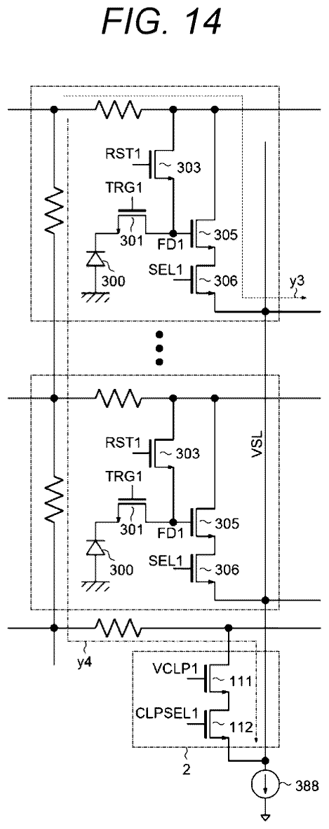

FIG. 14 is a circuit diagram around the clip circuit 2 according to one comparative example. As illustrated in FIG. 14, the clip circuit 2 according to One comparative example is connected in parallel to two or more pixel circuits 10c connected to the vertical signal line VSL.

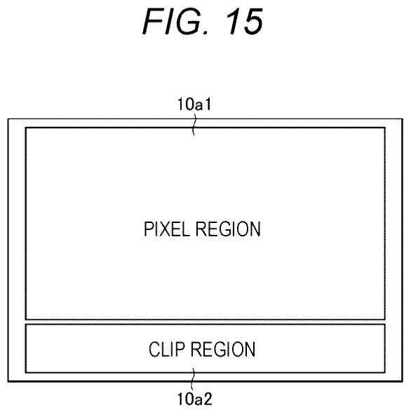

FIG. 15 is a diagram illustrating a configuration of the pixel array section 11 according to one comparative example. The pixel array section 11 according to one comparative example includes a pixel region 10al in which a plurality of pixels 10 is arranged, and a clip region 10a2 in which a plurality of clip circuits 2 is arranged for each vertical signal line VSL. The clip region 10a2 is arranged, for example, on the lower end portion side of the pixel array section 11.

The clip circuit 2 according to one comparative example is connected to each vertical signal line VSL separately from the plurality of pixel circuits 10c connected to each vertical signal line VSL. The common power supply voltage line VDDH is connected to the plurality of pixel circuits 10c and the clip circuit 2 connected to the same vertical signal line VSL, but the power supply voltage line VDDH is routed over a long distance, and thus a wiring load corresponding to the pixel position is superimposed. FIG. 14 illustrates a current path (indicated by an arrow line y3) flowing through the power supply voltage line VDDH at the time of the normal pixel signal readout, and a current path (indicated by an arrow line y4) flowing through the power supply voltage line VDDH at the time of the clipping.

As can be seen from the arrow lines y3 and y4, the current path flowing through the power supply voltage line VDDH is different between the time of the normal pixel signal readout and the time of the clipping, and an IR drop amount in the vertical signal line VSL varies significantly depending on the position of the pixel to be read out.

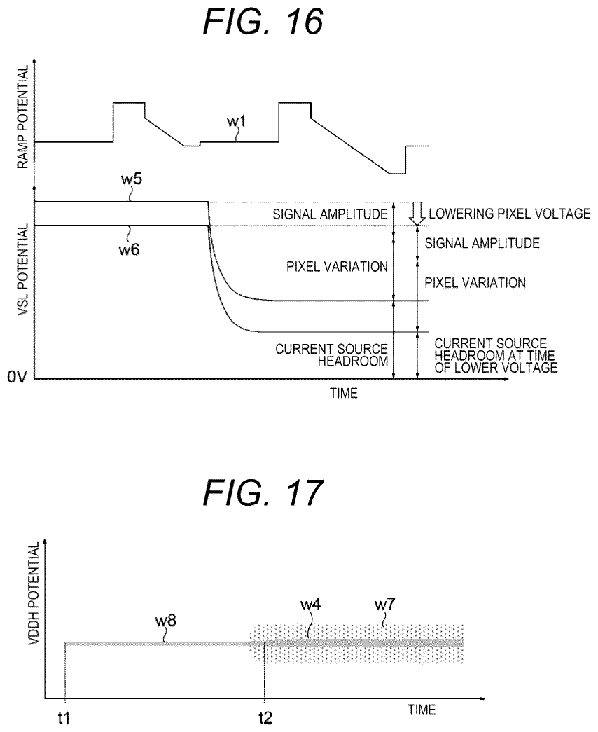

FIG. 16 is a diagram illustrating a voltage waveform of the vertical signal line VSL in a case of clipping the vertical signal line VSL, in the imaging device 1004 according to one comparative example. FIG. 16 illustrates a waveform w1 of the reference signal, a waveform w5 of the vertical signal line VSL at the time of the clipping in a case where the power supply voltage of the imaging device 1004 is not lowered, and a waveform w6 of the vertical signal line VSL at the time of the clipping in a case where the power supply voltage is lowered. In one comparative example, since the current paths flowing through the power supply voltage line VDDH differ between the time of the normal pixel signal readout and the time of the clipping, the voltage level of the vertical signal line VSL varies significantly depending on the pixel position. In particular, in a case where the power supply voltage of the pixel circuit 10c is lowered, the voltage fluctuation in the vertical signal line VSL due to the pixel variation is increased. Therefore, the design margin of the current source 388 becomes significantly narrower compared to the clip circuit 2 of the first embodiment, the design of the current source 388 is made difficult, and the reliability of the current source 388 is reduced.

FIG. 17 is a diagram illustrating how the voltage level of the power supply voltage line VDDH of the pixel circuit 10c fluctuates due to the pixel variation. In FIG. 17, the horizontal axis represents time, and the vertical axis represents a voltage level. In FIG. 17, a period from time t1 to time t2 indicates the voltage level of the power supply voltage line VDDH at the time of the normal pixel signal readout, and a period after time t2 indicates the voltage level of the power supply voltage line VDDH at the time of the clipping. FIG. 17 illustrates a waveform w7 of the power supply voltage line VDDH at the time of the normal pixel signal readout in one comparative example, a waveform 8 of the power supply voltage line VDDH at the time of the clipping in one comparative example, and the waveform w4 of the power supply voltage line VDDH at the time of the clipping in the first embodiment illustrated in FIG. 13.

As can be seen from the comparison between waveforms w7 and w4 in FIG. 17, the fluctuation amount in the power supply voltage line VDDH due to the pixel variation at the time of the clipping is significantly greater in the imaging device 1004 according to one comparative example than in the imaging device 1004 according to the first embodiment. Therefore, in the imaging device 1004 according to one comparative example, the voltage fluctuations in the power supply voltage line VDDH and the vertical signal line VSL due to the pixel variation become larger, streaking is easily visually recognized, and the image quality of the captured image deteriorates.

As described above, since the clip circuit 2 according to the first embodiment causes the current flowing through the power supply voltage line VDDH of the pixel circuit 10c connected to the corresponding divided VSL to flow to the current source 388 through the clip circuit 2, a large difference does not occur in the current path flowing to the current source 388 between the time of the clipping and the time of the normal pixel signal readout, and the pixel variation in the voltage level of the divided VSL can be suppressed even in a case where the voltage is lowered.

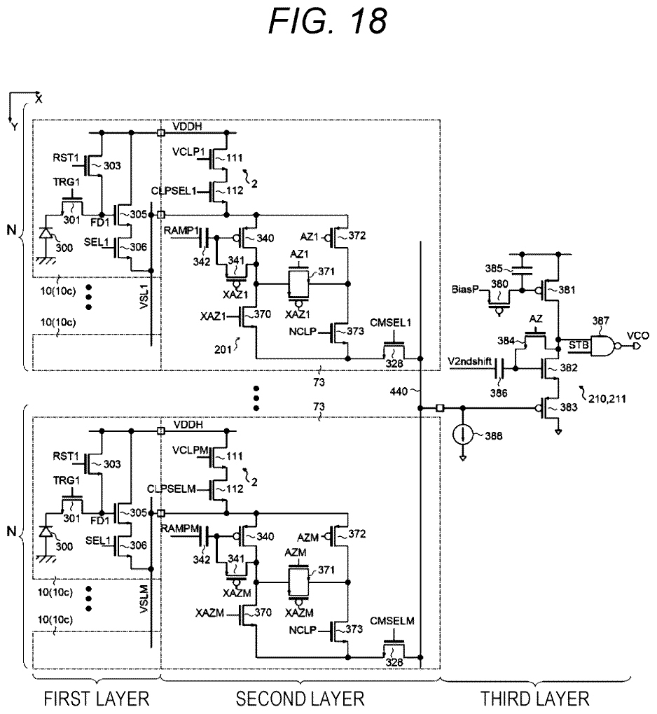

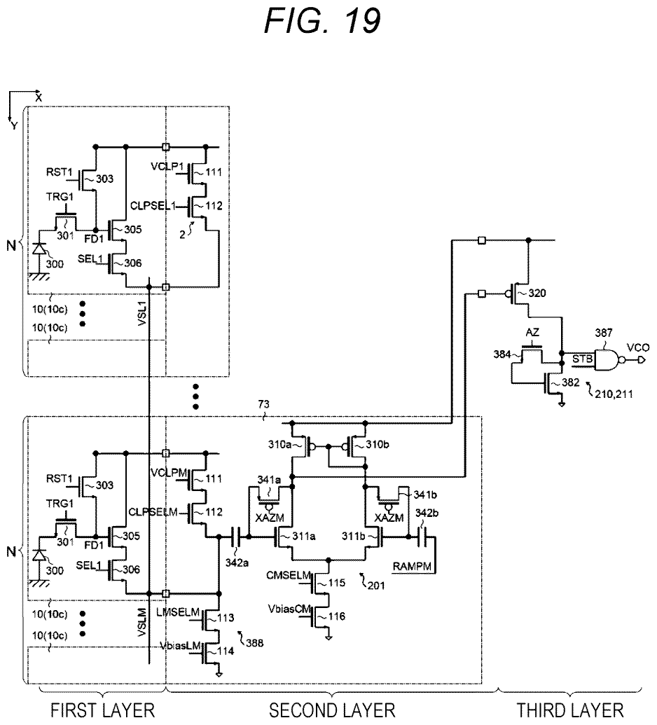

Various modification examples can be considered for the circuit configuration of the first-stage comparator 201 illustrated in FIG. 10. FIG. 18 is a circuit diagram around the first-stage comparator 201 of the imaging device 1004 according to a first modification example of the first embodiment.

In the first-stage comparator 201 illustrated in FIG. 18, the readout operation of a photoelectric conversion element 300 in the pixel circuit 10c is controlled by signals TRG1, RST1, and SEL1, which are supplied on a per-row basis from the vertical scanning circuit 12. The readout operation of the photoelectric conversion element 300 in the adjacent first-stage comparator 201 is controlled by signals TRG2, RST2, and SEL2, which are also supplied on a per-row basis from the vertical scanning circuit 12.

The first-stage comparator 201 is controlled by signals AZ1 and XAZ1, which are inverted with respect to each other, and a signal NCLP, all of which are supplied on a per-row basis from the vertical scanning circuit 12 to the first-stage comparator 201. Furthermore, the connection between the first-stage comparator 201 and an intermediate-stage comparator input line 440 is controlled by a signal CMSEL1 supplied on a per-row basis from the vertical scanning circuit 12 to the first-stage comparator 201.

The operation of the first-stage comparator 201 is controlled by signals AZ2 and XAZ2, which are inverted with respect to each other, and the signal NCLP, all of which are supplied on a per-row basis from the vertical scanning circuit 12 to the first-stage comparator 201. Moreover, the connection between the first-stage comparator 201 and the input node of the intermediate-stage comparator 202 is controlled by a signal CMSEL2 supplied on a per-row basis from the vertical scanning circuit 12 to the first-stage comparator 201.

The input node of the intermediate-stage comparator 202 is connected to the gate of a PMOS transistor 383 included in the second circuit 210, and also connected to the current source 388.

Note that each of signals TRG, RST, SEL, CMSEL, AZ, and NCLP (suffixes are omitted) is generated in the logic circuit 40 of the memory+logic section 2011, and supplied to the first-stage comparator 201 through the vertical scanning circuit 12.

The operation of the first-stage comparator 201 will be schematically described. The first-stage comparator 201 performs an auto-zero (AZ) operation before the P phase period. In the auto-zero operation, a switch circuit 341 including the PMOS transistor is turned on by the signal XAZ1, a PMOS transistor 340 is set in a diode connection state, a PMOS transistor 372 is turned off by the signal AZ1 that is the inverted signal of the signal XAZ1, and an NMOS transistor 370 is also turned off by the signal XAZ1. On the other hand, a switch circuit 371 is turned on by the signals AZ1 and XAZ1.

For example, the pixel signal output from the pixel circuit 10c is input to the drain of an NMOS transistor 373 through the PMOS transistor 340, which is set in a diode connection state, and through the switch circuit 371. The NMOS transistor 373 is turned on by the signal NCLP, and the pixel signal input to the drain of NMOS transistor 373 is input to one end of a switch circuit. 328. In a case where the switch circuit 328 is turned on by the signal CMSEL1, the pixel signal is supplied to the input line 440 of the intermediate-stage comparator 202 through the switch circuit 328, and is thereby connected to the current source 388. Therefore, the first-stage comparator 201 is reset.

After the auto-zero operation ends, the switch circuits 341 and 371 are turned off by the signals AZ1 and XAZ1. On the other hand, the PMOS transistor 372 and the NMOS transistor 370 are turned on by the signals AZ1 and XAZ1, and two current paths in the vertical direction in the drawing are configured.

In this state, the 0/1 determination is performed by the intermediate-stage comparator 202 in the second circuit 210 on the basis of the difference in the amount of the current flowing through the two current paths, according to the currents by the signal of the VSL1 by the pixel signal output from the pixel circuit and the RAMP signal.

The second circuit 210 illustrated in FIG. 18 includes PMOS transistors 380, 381, and 383, NMOS transistors 382 and 384, the capacitors 385 and 386, and the NAND circuit 387.

The input line 440 of the intermediate-stage comparator 202 is connected to the gate of the PMOS transistor 383. The drain of the PMOS transistor 383 is connected to a first fixed potential, and the source thereof is connected to the source of the NMOS transistor 382. The drain of the NMOS transistor 384 is connected to the drain of the NMOS transistor 382, and the source of the NMOS transistor 384 is connected to the gate of the NMOS transistor. The signal AZ is input to the gate of the NMOS transistor 384. Furthermore, a signal V2ndSHIFT is input through the capacitor 386 to a connection point where the gate of the NMOS transistor 382 and the source of the NMOS transistor 384 are connected. In this manner, a comparator that performs a comparison operation on the signal supplied from the input line 440 of the intermediate-stage comparator 202 is configured using the NMOS transistors 382 and 384 and the capacitor 386.

On the other hand, a bias voltage BaisP is input to the source of the PMOS transistor 380, and the drain of the PMOS transistor 380 is connected to the gate of the PMOS transistor 381. The other end of the capacitor 385, of which one end is connected to a second fixed voltage, is connected to a connection point where the drain of the PMOS transistor 380 and the gate of the PMOS transistor 381 are connected. The source of the PMOS transistor 381 is connected to the second fixed voltage, and the drain thereof is connected to the drain of the NMOS transistor 382.

An output signal is extracted from the connection point where the drain of the PMOS transistor 381 and the drain of the NMOS transistor 382 are connected, and is input to one input terminal of the NAND circuit 387. A signal STB is input to the other input terminal of the NAND circuit 387. The signal STB functions as a mask signal for masking a signal unnecessary for a comparator operation. The signal STB is generated, for example, in the logic circuit 40 of the memory+logic section 2011. The output of the NAND circuit 387 is an output signal from the second circuit 210 (intermediate-stage comparator 202).

The output of the NAND circuit 387 is input to the counter. Note that the stage following the NAND circuit 387 may be the third circuit.

In a case where the two transistors 111 and 112 in the clip circuit 2 of FIG. 18 are turned on, the current flows from the power supply voltage line VDDH of the pixel circuit 10c connected to the divided VSL, to the two transistors 111 and 112 in the clip circuit 2. This current flows to the current source 388 through the first-stage comparator 201. Also in the circuit configuration of FIG. 18, since there is no significant difference in the current path through the power supply voltage line VDDH between the time of the normal pixel signal readout and the time of the clipping, the IR drop amount in the divided VSL due to the pixel variation does not vary significantly, and thus the design margin of the current source can be sufficiently ensured as illustrated in FIG. 12.

FIGS. 10 and 18 illustrate an example in which the first circuit 73 of the comparator 20 is arranged on the second layer 2010b and the second circuit 210 and the third circuit 211 are arranged on the third layer 2010c, but a part of the first circuit 73 may be arranged on the third layer 2010c. For example, the first-stage comparator 201 in the first circuit 73 may be arranged on the third layer 2010c, and the rest of the first circuit 73 including the clip circuit 2 may be arranged on the second layer 2010b. Furthermore, the current source that generates a current flowing through the clip circuit 2 may be arranged on either the second layer 2010b or the third layer 2010c. For example, only the clip circuit 2 in the first circuit 73 may be arranged on the second layer 2010b, and the rest of the first circuit 73 may be arranged on the third layer 2010c.

FIGS. 10 and 18 illustrate an example in which the first circuit 73 of the comparator 20 is connected for each divided VSL obtained by dividing the vertical signal line VSL into a plurality of sections in the vertical direction, but a configuration may be adopted in which the first circuit 73 of the comparator 20 is connected without dividing the vertical signal line VSL.

FIG. 19 is a circuit diagram around the first-stage comparator 201 of the imaging device 1004 according to a second modification example of the first embodiment. The plurality of pixel circuits 10c is connected to the vertical signal line in FIG. 19, and one comparator 20 is connected thereto. More specifically, one comparator 20 is connected to the N pixel circuits 10c connected to the vertical signal line VSL.

The first circuit 73 in the comparator 20 includes the clip circuit 2, the first-stage comparator 201, and the current source. The first-stage comparator 201 in FIG. 19 includes a differential comparator having a circuit configuration similar to that of the first-stage comparator 201 in FIG. 10.

Also in FIG. 19, since there is no significant difference between the current path from the power supply voltage line VDDH of the pixel circuit 10c when the transistors 111 and 112 in the clip circuit 2 are turned on, and the current path through the vertical signal line at the time of the normal pixel signal readout, the difference in the IR drop amount in the vertical signal line VSL due to the pixel variation is decreased, and thus the design margin of the current source can be sufficiently ensured.

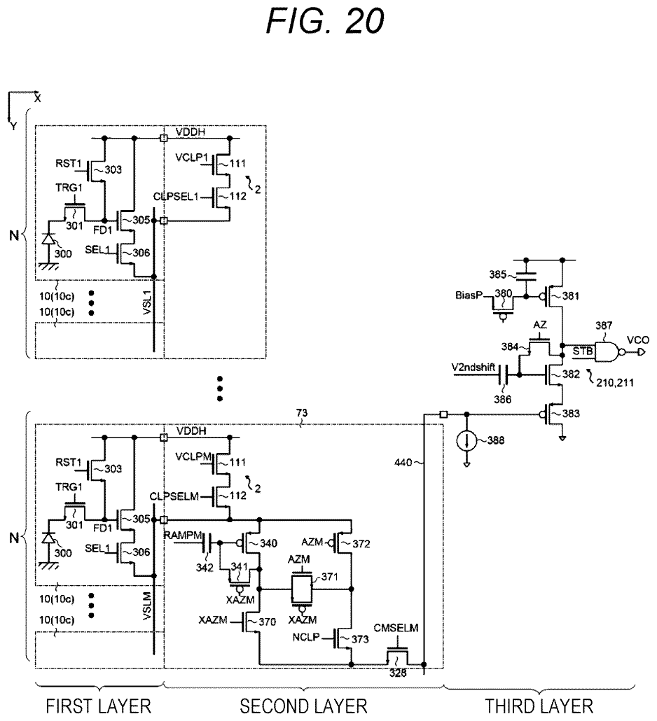

FIG. 20 is a circuit diagram around the first-stage comparator 201 of the imaging device 1004 according to a third modification example of the first embodiment. Similar to FIG. 19, the plurality of pixel circuits 10c is connected to the vertical signal line in FIG. 20, and one comparator 20 is connected thereto.

The first circuit 73 in the comparator 20 includes the clip circuit 2, the first-stage comparator 201, and the current source 388. The first-stage comparator 201 in FIG. 20 includes a differential comparator having a circuit configuration similar to that of the first-stage comparator 201 in FIG. 18. Therefore, effects similar to those of the imaging device 1004 in FIGS. 18 and 19 can be obtained.

Various modification examples are also conceivable for the imaging device 1004 that connects the plurality of pixel circuits 10c and one comparator 20 to the vertical signal line illustrated in FIGS. 19 and 20. For example, FIGS. 19 and 20 illustrate an example in which the first circuit 73 of the comparator 20 is arranged on the second layer 2010b and the second circuit 210 and the third circuit 211 are arranged on the third layer 2010c, but a part of the first circuit 73 may be arranged on the third layer 2010c. For example, the first-stage Comparator 201 in the first circuit 73 may be arranged on the third layer 2010c, and the rest of the first circuit 73 including the clip circuit 2 may be arranged on the second layer 2010b. Furthermore, the current: source ; that generates a current flowing through the clip circuit 2 may be arranged on either the second layer 2010b or the third layer 2010c. For example, only the clip circuit 2 in the first circuit 73 may be arranged on the second layer 2010b, and the rest of the first circuit 73 may be arranged on the third layer 2010c.

As described above, in the first embodiment, since the clip circuit 2 connected to the power supply voltage line VDDH of the pixel circuit 10c to be read out is provided in the first circuit 73 of the comparator 20, no significant difference arises between the current path through the power supply voltage line VDDH at the time of the clipping and the current path through the vertical signal line (or divided VSL) at the time of the normal pixel signal readout, and the difference in the IR drop amount in the divided VSL due to the pixel variation is eliminated. Therefore, the design margin of the current source can be increased, the design of the current source can be facilitated, and the reliability of the current Source can be improved.

### Second Embodiment

In a second embodiment, the load on the output node of the first circuit 73 of the comparator 20 is reduced.

As illustrated in FIG. 9, by dividing the vertical signal line VSL into a plurality of divided VSLs and connecting the first circuit 73 of the comparator 20 to each divided VSL, the load on the vertical signal line VSL can be reduced. However, while the first circuit 73 of the comparator 20 is provided in a number equal to the number of the divided VSLs, the number of the second circuit 210 is only one. Therefore, the input load of the second circuit 210 is increased.

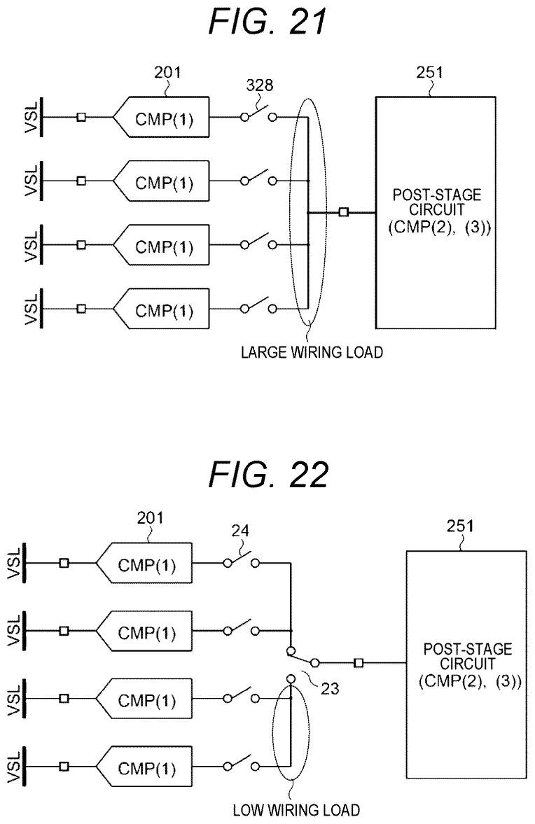

FIG. 21 is a block diagram illustrating a schematic configuration of the comparator 20 according to the first embodiment. As illustrated in FIG. 21, the comparator 20 according to the first embodiment includes the first-stage comparators 201 in a plurality of first circuits 73 connected to a plurality of divided VSLs, a plurality of switches 328 connected to the output nodes of the plurality of first circuits 73, and the post-stage circuit 251 including the second circuit 210 and the third circuit 211 connected to the plurality of switches 328.

Any one of the plurality of switches 328 is turned on, and an output signal of the corresponding first circuit 73 is input to the second circuit 210. Since the plurality of switches 328 is integrated into one wiring and connected to the second circuit 210, this wiring load is increased, and settling takes time, so that the frame rate cannot be increased.

FIG. 22 is a block diagram illustrating a schematic configuration of the comparator 20 according to the second embodiment. As illustrated in FIG. 22, the comparator 20 according to the second embodiment is provided with a first selector 23 that divides the output wirings of the plurality of first circuits 73 connected to the plurality of divided VSLs, into a plurality of sets and selects one of the plurality sets. Furthermore, each set includes output wirings of two or more first-stage comparators 201, and a second selector 24 that selects one of the output wirings of two or more first-stage comparators 201 of each set is provided.

As illustrated in FIG. 22, by providing the first selector 23 and the second selector 24 between the plurality of first-stage comparators 201 and the single second circuit 210 of the comparator 20, the output. signal of the first-stage comparator 201 selected by the first selector 23 and the second selector 24 is input to the second circuit 210. Since the output nodes of the plurality of first-stage comparators 201 are divided into a plurality of sets by the first selector 23, the load of the input wiring of the second circuit 210 can be reduced.

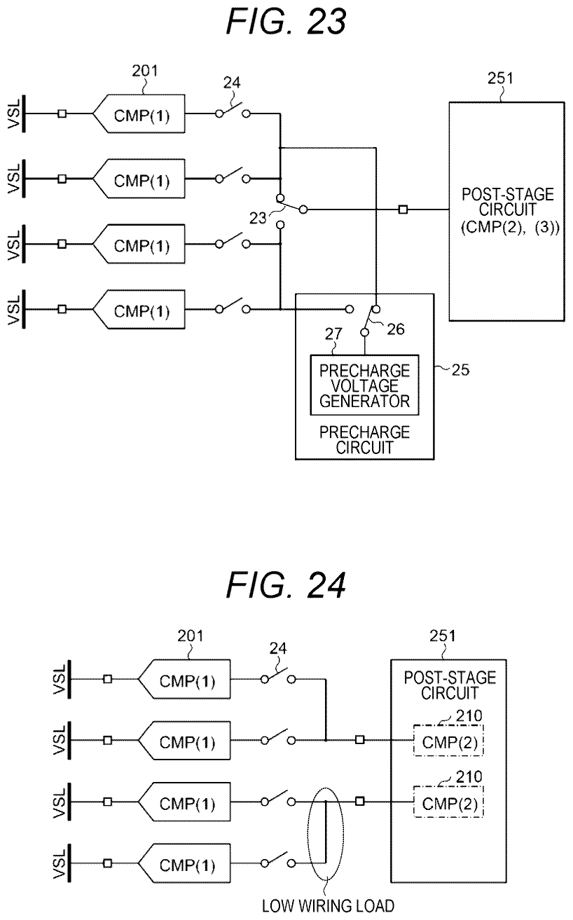

FIG. 23 is a block diagram illustrating a schematic configuration of the comparator 20 according to a first modification example of the second embodiment. The comparator 20 of FIG. 23 includes a precharge circuit 25 in addition to the configuration of FIG. 22.

The precharge circuit 25 includes a third selector 26 and a precharge voltage generator 27. The third selector 26 selects the output wiring of the first-stage comparator 201 that has not been selected by the first selector 23. The precharge voltage generator 27 generates a precharge voltage.

In this manner, the precharge circuit 25 precharges the output wiring of the first-stage comparator 201 that has not been selected by the first selector 23, to a predetermined voltage level. By precharging the output wiring of the first-stage comparator 201 that has not been selected by the first selector 23, when the precharged output wiring of the first-stage comparator 201 is later selected by the first selector 23, the output wiring of the first-stage comparator 201 can be quickly set to the desired voltage level, the settling time can be shortened, and the frame rate can be increased.

FIG. 24 is a block diagram illustrating a schematic configuration of the comparator 20 according to a second modification example of the second embodiment. FIG. 24 is obtained by removing the first selector 23 from the comparator 20 of FIG. 22. In the comparator 20 of Fig. 24, the output wirings of the plurality of first-stage comparators 201 are divided into a plurality of sets, and the second circuit 210 is provided for each set. Therefore, the comparator 20 in FIG. 24 includes a plurality of second circuits 210 in a number equal to the number of the plurality of sets. One of the output wirings of the plurality of first-stage comparators 201 belonging to each set is selected by the second selector 24, and is input to the corresponding second circuit 210.

In the comparator 20 of FIG. 24, the first selector 23 can be omitted, and the number of second circuits 210 is increased compared to that in FIG. 22.

Hereinafter, a specific circuit example Corresponding to the block diagram of FIG. 23 will be described, but the circuit diagram can be changed to a circuit diagram corresponding to the block portion of FIG. 22 or 24 by changing a part of the circuit configuration.

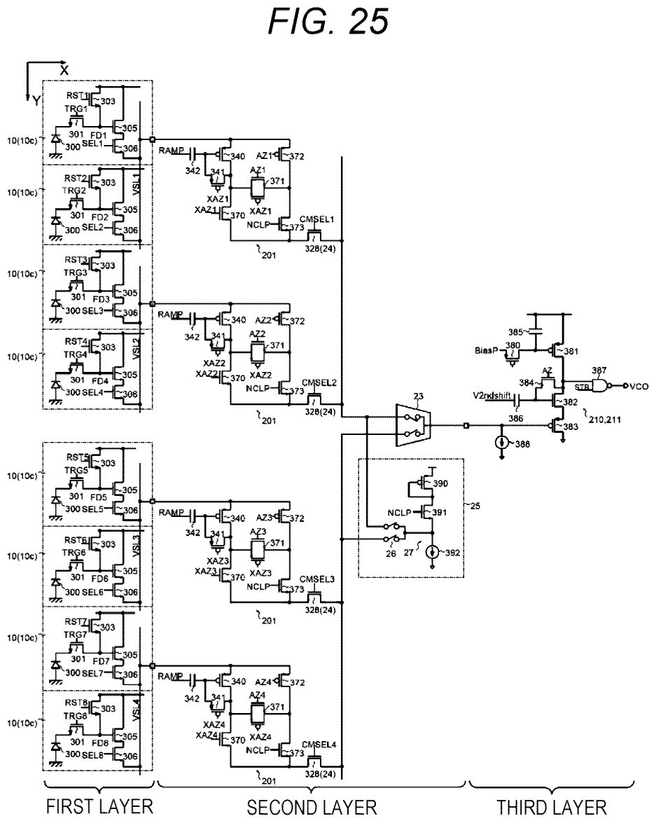

FIG. 25 is a circuit diagram around the first-stage comparator 201 of the imaging device 1004 according to the second embodiment. One first circuit 73 is provided for each of the plurality of divided VSLs. One second circuit 210 and one third circuit 211 are provided for the plurality of first circuits 73 corresponding to the plurality of divided VSLS.

The first circuit 73 includes the first-stage comparator 201, the first selector 23, the second selector 24, and the precharge circuit 25. The first-stage comparator 201 in first circuit 73 and the second circuit 210 have a circuit configuration similar to that in FIG. 18. The first circuit 73 is arranged on the second layer 2010b, and the second circuit 210 is arranged on the third layer 2010c.

FIG. 25 illustrates an example in which the output wirings of four first circuits 73 connected to the divided VSLs are divided into two sets. The first selector 23 selects one of the two sets. The second selector 24 includes transistors 328 connected to the output nodes of the respective first-stage comparators 201.

The second selector 24 selects any one of the output signals from the two first circuits 73 belonging to each set, and allows the output signal to input to the second selector 24.

The precharge circuit 25 includes the third selector 26 and the precharge voltage generator 27. The third selector 26 selects one of the output wirings of the first circuits 73 of each set. The third selector 26 selects whether or not to connect the sources of the transistors 328 of each set to the output node of the precharge voltage generator 27.

The precharge voltage generator 27 includes a PMOS transistor 390, an NMOS transistor 391, and a current source 392, which are connected in series between a power supply line and a ground line. The drain and gate of the PMOS transistor 390 are short-circuited. An NCLP signal is input to the gate of the NMOS transistor 391. The NCLP signal goes to a high level when precharging is performed. In a case where the NCLP signal goes to a high level, the NMOS transistor 391 is turned on, and the precharge voltage is output from the source of the NMOS transistor 391. Note that the circuit configuration of the precharge voltage generator 27 is not limited to the example illustrated in FIG. 25.

In FIG. 25, the output wirings of two first circuits 73 are grouped as one set, but the number of output wirings of the first circuits 73 constituting each set is arbitrary. Furthermore, the number of divisions of the vertical signal line VSL is also arbitrary. Furthermore, the circuit configuration of the first-stage Comparator 201 in the first circuit 73 is not limited to that illustrated in FIG. 25. For example, a differential Comparator circuit illustrated in FIG. 10 may be used, or any other circuit configuration may be adopted. Furthermore, the circuit configuration of the second circuit 210 is not limited to that illustrated in FIG. 25, and may be, for example, the one illustrated in FIG. 10 or any other suitable configuration.

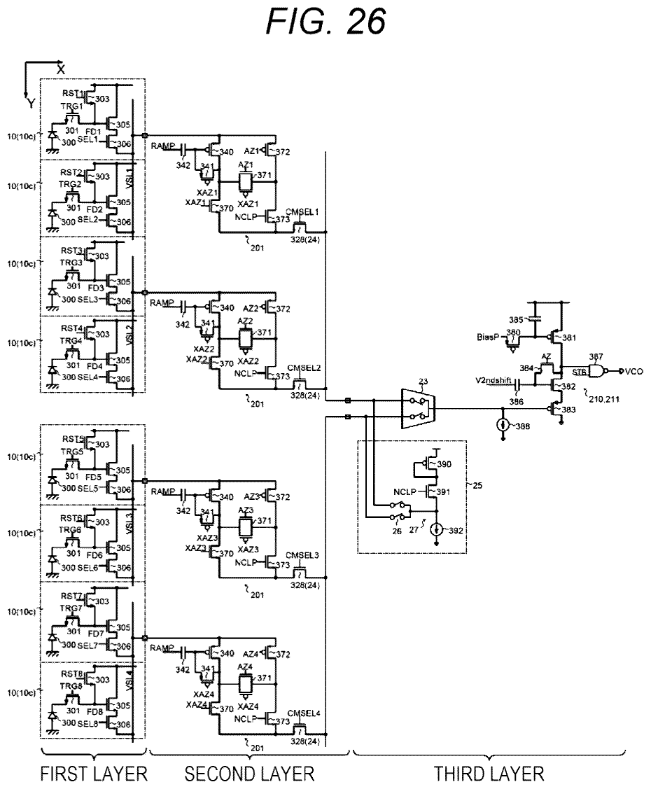

FIG. 26 is a circuit diagram around the first-stage comparator 201 of the imaging device 1004 according to a modification example of the second embodiment. The circuit configuration of the first-stage comparator 201 in FIG. 26 is the same as that in FIG. 25. FIG. 26 differs from FIG. 25 in that the first selector 23 and the precharge circuit 25 are moved from the first circuit 73 to the second circuit 210. Thus, in FIG. 26, the second circuit 210 including the first selector 23 and the precharge circuit 25 is arranged on the third layer 2010c.

As described above, in the second embodiment, the output wirings of the plurality of first circuits 73 in the comparator 20 are divided into a plurality of sets, and the first selector 23 that selects one of the sets is provided, and the second selector 24 that selects one of the output wirings of the plurality of first circuits 73 in the selected set. Therefore, the load of the input wiring of the second circuit 210 can be reduced, the settling time can be shortened, and the frame rate can be increased.

Furthermore, in the second embodiment, since the precharge circuit 25 that precharges the output wirings of the first circuits 73 in the set that has not been selected is provided, when the set that has not been selected is later selected, the output wiring of the first circuit 73 can be quickly set to the desired voltage level, and the settling time can be further shortened.

### Third Embodiment

In a third embodiment, the divided VSL that has not been selected is set to a predetermined voltage level.

In a case where the vertical signal line VSL is divided into a plurality of divided VSLs, and a plurality of first circuits 73 and a single second circuit 210 of the comparator 20 are provided for the plurality of divided VSLs, one output among the plurality of first circuits 73 is input to the second circuit 210. In this case, in a case where the divided VSLs connected to the remaining first circuits 73 are set to a high-impedance state, when the pixel signals of the divided VSLs in the high-impedance state are read out afterward, the voltage level on the divided VSL is rapidly changed, an instantaneous large current flows through the power supply line of the pixel circuit 10c, and thus the characteristics may deteriorate. Therefore, the imaging device 1004 according to the third embodiment is characterized by implementing countermeasures against such a problem.

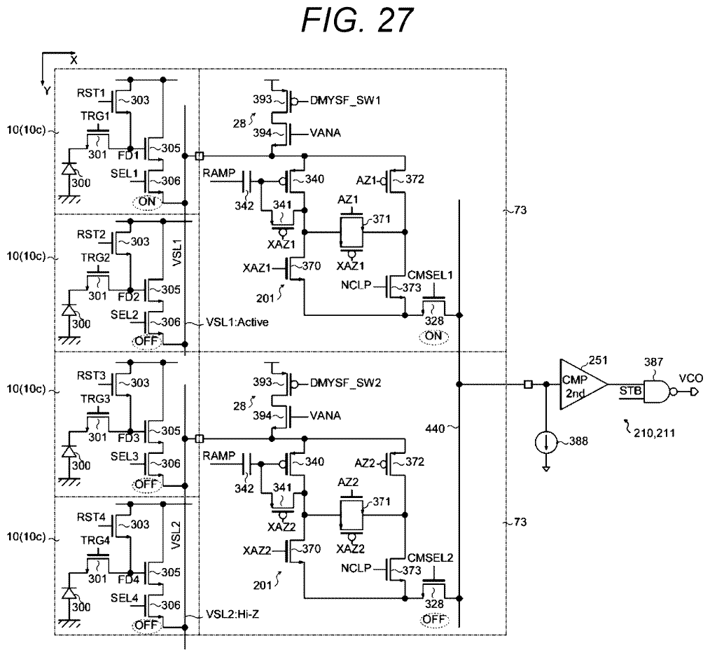

FIG. 27 is a circuit diagram around the first-stage Comparator 201 of the imaging device 1004 according to the third embodiment. As illustrated in FIG. 27, the imaging device 1004 according to the third embodiment includes the first circuit 73 of the comparator 20 for each of the plurality of divided VSLs. One second circuit 210 of the comparator 20 is provided for the plurality of first circuits 73 corresponding to the plurality of divided VSLs.

The first circuit 73 includes the first-stage comparator 201 and a voltage setting circuit 28. The first-stage comparator 201 has, for example, the same circuit configuration as the first-stage comparator 201 in FIG. 18. Note that the circuit configuration of the first-stage comparator 201 in the third embodiment is not limited to that illustrated in FIG. 27, and may be, for example, a circuit configuration similar to that of the differential comparator circuit in FIG. 10, or may be another circuit configuration.

The voltage setting circuit 28 includes a PMOS transistor 393 and an NMOS transistor 394 that are cascode-connected between the power supply line and the ground line. The power supply voltage of the power supply line is the same as the power supply voltage of the power supply line of the pixel circuit 10c. A DMYSF_SW1 signal is input to the gate of the PMOS transistor 393. A VANA signal is input to the gate of the NMOS transistor 394. The NMOS transistor 394 is a source follower circuit. Therefore, in a case where the DMYSF_SW1 signal goes to a low level, the PMOS transistor 393 is turned on, and the power supply line goes to a voltage level corresponding to the voltage level of the VANA signal. The DMYSF_SW1 signal goes to a high level only in any first circuit 73 among the plurality of first circuits 73 connected to the divided VSLs. That is, different DMYSF_SW signals are input to the plurality of first circuits 73 connected to the divided VSLs. The voltage level of the VSL of the first circuit 73 can be adjusted by the voltage level of the VANA signal. As described above, the voltage setting circuit 28 includes a dummy source follower circuit having the same circuit configuration as those of an amplifier transistor 305 and a selection transistor 306 constituting the source follower circuit in the pixel circuit. The dummy source follower circuit sets the corresponding divided VSL to a predetermined voltage level.

The transistors 393 and 394 are source follower circuits that have the same electrical characteristics as those of the amplifier transistor 305 and the selection transistor 306 in the pixel circuit 10c.

In the following, among the plurality of first circuits 73 connected to the plurality of divided VSLS, the first circuit 73 that supplies the output signal to the second circuit 210 is referred to as being in an active state, and the first circuit 73 that does not supply the output signal to the second circuit 210 is referred to as being in an inactive state.

In the imaging device 1004 according to the third embodiment, since the divided VSL connected to the first circuit 73 in the inactive state is forcibly set to the predetermined voltage level using the voltage setting circuit 28, when the first circuit 73 transitions from the inactive state to the active state, the voltage level of the divided VSL does not fluctuate significantly, and an instantaneous large current does not flow through the power supply line of the pixel circuit 10c.

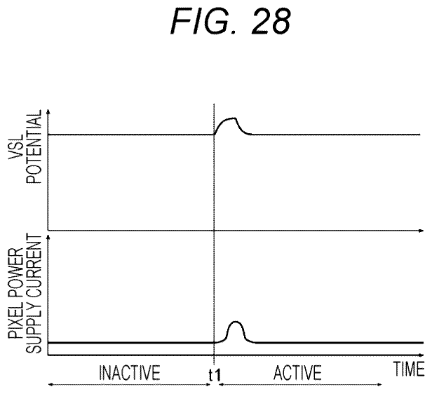

FIG. 28 is a diagram illustrating a voltage waveform of the divided VSL illustrated in FIG. 27 and a current waveform flowing through the power supply voltage line VDDH of the pixel circuit 10c. A period before time t1 in FIG. 28 corresponds to the inactive state, and a period after time t1 corresponds to the active state.

Since the state transits from the inactive state to the active state at time t1, the voltage level of the divided VSL fluctuates slightly, but the fluctuation amount is not significant.

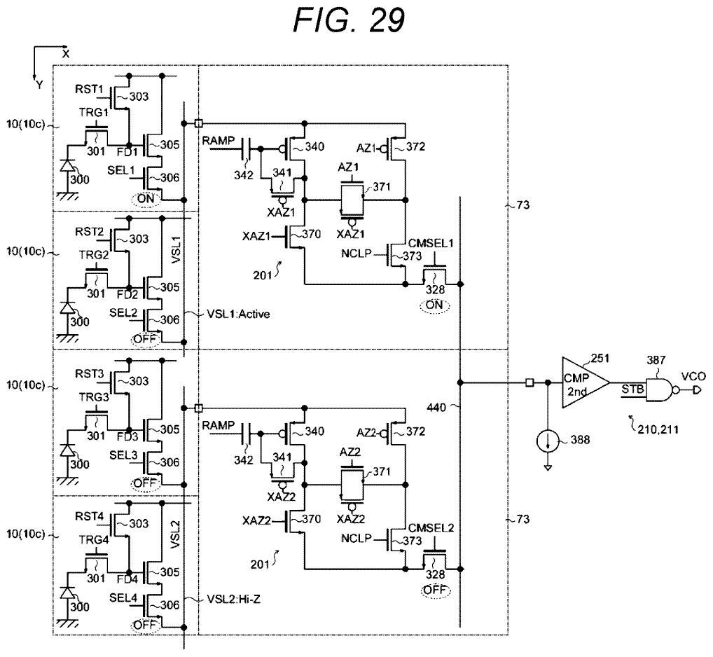

FIG. 29 is a circuit diagram around the first-stage Comparator 201 of the imaging device 1004 according to one comparative example. The first circuit 73 of the imaging device 1004 according to one comparative example is different from the first circuit 73 of the imaging device 1004 according to the third embodiment illustrated in FIG. 28 in that the voltage setting circuit 28 is not provided.

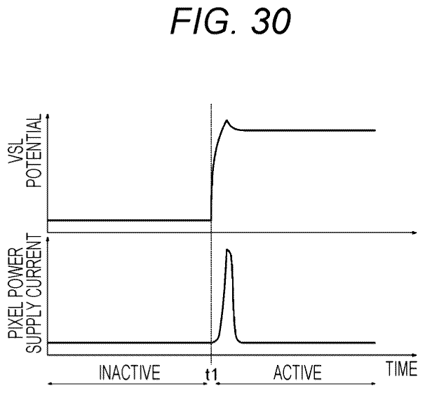

FIG. 30 is a diagram illustrating a voltage waveform of the divided VSL illustrated in FIG. 29 and a current waveform flowing through the power supply voltage line VDDH of the pixel circuit 10c. In the first circuit 73 according to one comparative example, when the state is switched from the inactive state to the active state (time t1), an instantaneous large current flows through the power supply voltage line VDDH of the pixel circuit 10c, and also the voltage level of the divided VSL fluctuates instantaneously and significantly.

As can be seen from a comparison between the voltage waveforms and current waveforms in FIGS. 30 and 28, by providing the voltage setting circuit 28 in the first circuit 73, when the first circuit 73 switches from the inactive state to the active state, an instantaneous large current no longer flows through the power supply voltage line VDDH of the pixel circuit 10c, and the voltage fluctuation in the divided VSL can also be suppressed.

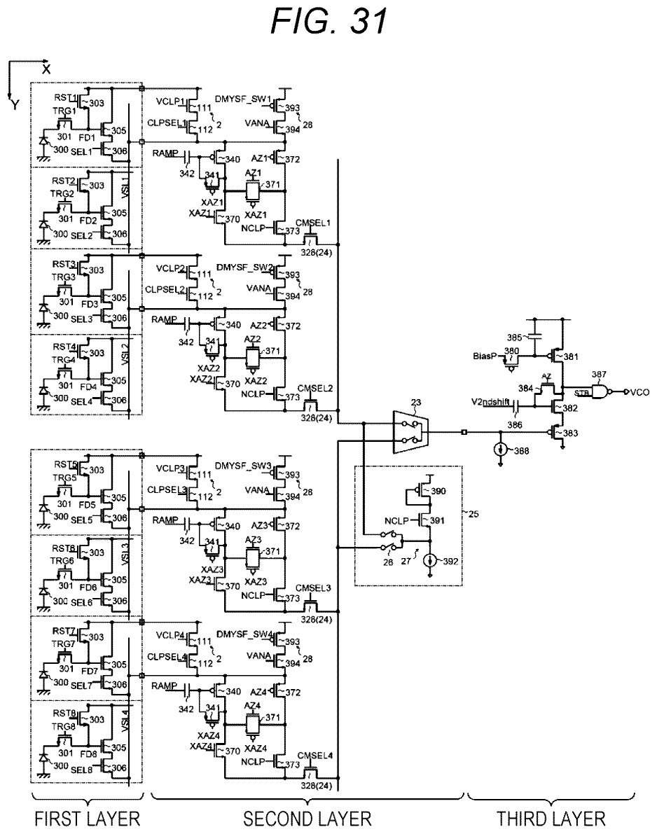

The characteristic functions of the imaging device 1004 according to the first to third embodiments described above can be arbitrarily combined. FIG. 31 is a circuit diagram around the first-stage comparator 201 of the imaging device 1004 having characteristic functions according to the first to third embodiments.

The first circuit 73 illustrated in FIG. 31 includes the clip circuit 2, the first selector 23, the second selector 24, the precharge circuit 25, and the voltage setting circuit 28, in addition to the first-stage comparator 201.

The first-stage comparator 201 in FIG. 31 may have a circuit configuration other than the illustrated circuit configuration. The circuit configuration of the second circuit 210 is also arbitrary.

As a modification example of FIG. 31, instead of including the clip circuit 2 and the voltage setting circuit 28, the first circuit 73 that does not include the first selector 23, the second selector 24, and the precharge circuit 25 is also conceivable. In addition, the first circuit 73 having any two of the clip circuit 2, the first selection circuit, the second selection circuit, the precharge circuit 25, and the voltage setting circuit 28 is also conceivable.

As described above, in the third embodiment, for the first circuit 73 in the inactive state among the plurality of first circuits 73 connected to the plurality of divided VSLs, since the voltage setting circuit 28 sets the divided VSL to the predetermined voltage level, when the state transitions from the inactive state to the active state, an instantaneous large current does not flow through the power supply voltage line VDDH of the pixel circuit 10c, and the voltage fluctuation of the divided VSL can be suppressed.

### Fourth Embodiment

Next, a fourth embodiment of the present disclosure will be described. A fourth embodiment illustrates a specific structure in a case where the imaging device 1004 described using the first to fourth embodiments is configured as one solid-state imaging element 2000a.

### First Example

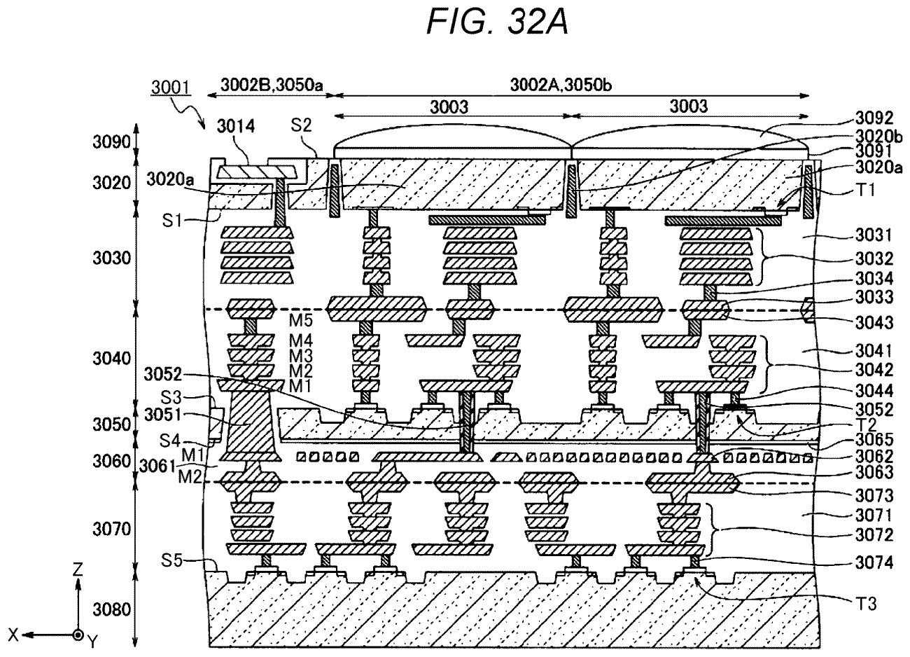

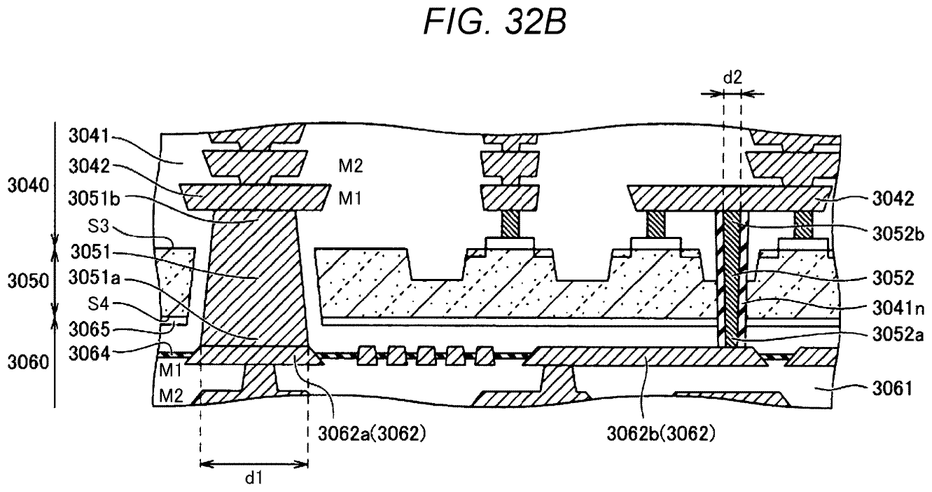

Next, a first example of the fourth embodiment will be described. FIGS. 32A and 32B are schematic diagrams illustrating a sectional structure of an example of an imaging device 3001 according to the first example of the fourth embodiment. The imaging device 3001 may be associated with the imaging device 1004 described using the first to fourth embodiments.

### Stacked Structure of Solid-State Imaging Element

As illustrated in FIG. 32A, the imaging device 3001 has a stacked structure in which a light condensing layer 3090, a first semiconductor layer 3020, a first wiring layer 3030, a second wiring layer 3040, a second semiconductor layer 3050, a third wiring layer 3060, a fourth wiring layer 3070, and a third semiconductor layer 3080 are stacked in this order.

The light condensing layer 3090 has a stacked structure in which, for example, a color filter 3091 and an on-chip lens 3092 are stacked in this order from a second surface S2 side of the first semiconductor layer 3020, although not limited thereto. The first semiconductor layer 3020 has a photoelectric conversion region to be described later, and one surface is a first surface S1 and the other surface is the second surface S2 which is a light incident surface. The first wiring layer 3030 is laminated onto the first surface S1 of the first semiconductor layer 3020. The second wiring layer 3040 is laminated onto a surface of the first wiring layer 3030 opposite to the surface on the first semiconductor layer 3020 side. The second semiconductor layer 3050 includes a plurality of transistors, one surface thereof is a third surface S3, the other surface thereof is a fourth surface S4, and the third surface S3 is laminated onto a surface of the second wiring layer 3040 opposite to the surface on the first wiring layer 3030 side. The third wiring layer 3060 is laminated onto the fourth surface S4 of the second semiconductor layer 3050. The fourth wiring layer 3070 is laminated onto a surface of the third wiring layer 3060 opposite to the surface on the second semiconductor layer 3050 side. A fifth surface S5 of the third semiconductor layer 3080 is laminated onto a surface of the fourth wiring layer 3070 opposite to the surface on the third wiring layer 3060 side.

Here, the first surface S1 of the first semiconductor layer 3020 may be also referred to as an element formation surface or a main surface, and the second surface S2 of the first semiconductor layer 3020 may be also referred to as a light incident surface or a back surface. Furthermore, the third surface S3 of the second semiconductor layer 3050 may be also referred to as an element formation surface or a main surface, and the fourth surface S4 of the second semiconductor layer 3050 may be also referred to as a back surface. Moreover, the fifth surface S5 of the third semiconductor layer 3080 may be also referred to as an element formation surface or a main surface, and a surface opposite to the fifth surface S5 may be referred to as a back surface.

Furthermore, the first semiconductor layer 3020 and the second semiconductor layer 3050 are bonded through the first wiring layer 3030 and the second wiring layer 3040 using a Face to Face (F2F) method, that is, with the element formation surfaces facing each other. Moreover, the second semiconductor layer 3050 and the third semiconductor layer 3080 are bonded through the third wiring layer 3060 and the fourth wiring layer 3070 using a Back to Face (B2F) method, that is, with the back surface and the element formation surface facing each other.

### First Semiconductor Layer

The first semiconductor layer 3020 includes a semiconductor substrate. The first semiconductor layer 3020 includes a single-crystal silicon substrate of a first conductivity type, for example, a p-type. Furthermore, for example, a bonding pad 3014 is provided in a region of the first semiconductor layer 3020 overlapping a peripheral region 3002B in plan view. Then, a photoelectric conversion region 3020a is provided for each pixel 3003 in a region of the first semiconductor layer 3020 overlapping the pixel region. For example, island-shaped photoelectric conversion regions 3020a partitioned by isolation regions 3020b are provided for each pixel 3003. Note that the number of pixels 3003 is not limited to that in FIG. 32A.

Although not illustrated, the photoelectric conversion region 3020a includes a well region of a first conductivity type, for example, a p-type, and a semiconductor region (photoelectric conversion section) of a second conductivity type, for example, an n-type, embedded in the well region. The photoelectric conversion element in the pixel 10 illustrated in FIG. 3 is configured in the photoelectric conversion region 3020a including the well region and the photoelectric conversion section of the first semiconductor layer 3020. Furthermore, although not limited thereto, the photoelectric conversion region 3020a may be provided with a charge storage region (not illustrated) which is a semiconductor region of the second conductivity type, for example, the n-type, and a transistor T1.

Although not limited to this configuration, the isolation region 3020b has a trench structure in which, for example, an isolation groove is formed in the first semiconductor layer 3020 and an insulating film is embedded in the isolation groove. In the example illustrated in FIG. 32A, an insulating film and metal are embedded in the isolation groove.

### First Wiring Layer

The first wiring layer 3030 includes an insulating film 3031, wirings 3032, a first connection pad 3033, and vias (contacts) 3034. As illustrated in the drawing, the wiring 3032 and the first connection pad 3033 are stacked with the insulating film 3031 interposed therebetween. The first connection pad 3033 faces the surface of the first wiring layer 3030 on a side opposite to the first semiconductor layer 3020 side. The vias 3034 connect the first semiconductor layer 3020 to the wiring 3032, the wirings 3032 to each other, and the wiring 3032 to the first connection pad 3033 or the like. Furthermore, the wiring 3032 and the first connection pad 3033 are not limited to this, but may include copper and be formed using a damascene process, for example.

### Second Wiring Layer

The second wiring layer 3040 includes an insulating film 3041, wirings 3042, a second connection pad 3043, and vias (contacts) 3044. As illustrated in the drawing, the wiring 3042 and the second connection pad 3043 are stacked with the insulating film 3041 interposed therebetween. The second connection pad 3043 faces the surface of the second wiring layer 3040 on a side opposite to the second semiconductor layer 3050 side, and is bonded to the first connection pad 3033. The vias 3044 connect the second semiconductor layer 3050 to the wiring 3042, the wirings 3042 to each other, and the wiring 3042 to the second connection pad 3043 or the like. Furthermore, the wiring 3042 and the second connection pad 3043 are not limited to this, but may include copper and be formed using a damascene process, for example.

### Second Semiconductor Layer

The second semiconductor layer 3050 includes a semiconductor substrate. Although not limited to this, the second semiconductor layer 3050 includes a single-crystal silicon substrate. The second semiconductor layer 3050 exhibits the first conductivity type, for example, the p-type. A plurality of transistors T2 is provided in the second semiconductor layer 3050. More specifically, the transistors T2 are provided in a region of the second semiconductor layer 3050 overlapping the pixel region. Note that, in the second semiconductor layer 3050, in order to distinguish the region overlapping the pixel region in plan view, the region overlapping the peripheral region around the pixel region in plan view, the region overlapping the peripheral region 3002B is referred to as a first region 3050a, and the region overlapping a pixel region 3002A is referred to as a second region 3050b.

### First Conductor and Second Conductor

The second semiconductor layer 3050 is provided with a first conductor 3051 and a second conductor 3052. More specifically, in the first region 3050a, the first conductor 3051 is provided that has a first width, includes a first material, and penetrates through the second semiconductor layer 3050 in a thickness direction. Then, in the second region 3050b, the second conductor 3052 is provided that has a second width smaller than the first width, includes a second material different from the first material, and penetrates through the second semiconductor layer 3050 in the thickness direction. The first conductor 3051 and the second conductor 3052 are conductors (electrodes) that penetrate the semiconductor layer. In the present embodiment, since the semiconductor layer includes silicon, the first conductor 3051 and the second conductor 3052 are through-silicon vias (TSVs).

Although not limited to this, the first conductor 3051 is used as, for example, a power supply line. Therefore, it is preferable that the first conductor 3051 has low electrical resistance. Accordingly, it is preferable to use a conductive material with low electrical resistivity as the first material constituting the first conductor 3051. Here, copper as an example of such a conductive material is used as the first material. Furthermore, by increasing the first width, the resistance of the first conductor 3051 can be reduced.

Since the arrangement density of elements and wirings is low in the first region 3050a where the first conductor 3051 is provided, the first width can be increased.

Since the second conductor 3052 is provided in the second region 3050b where the plurality of transistors T2 is provided, the second conductor 3052 needs to be provided in a narrow region between the transistors T2 in some cases. Therefore, it is necessary to reduce the second width. When the second width is reduced, the aspect ratio of the second conductor 3052 is increased. Although not limited to this, the aspect ratio of the second conductor 3052 is, for example, 5 or more in some cases. With such an aspect ratio, it is difficult to embed the same material as the first material (here, for example, copper) in some cases. Therefore, it is preferable to use a conductive material with good embeddability for a hole having a high aspect ratio, as the second material constituting the second conductor 3052. Examples of such a conductive material include a high-melting-point metal. Examples of the high-melting-point metal include tungsten (W), cobalt (Co), ruthenium (Ru), or a metal material containing at least one of these. Here, tungsten is used as the second material.

As illustrated in FIG. 32B, the first conductor 3051 has an end portion 3051a and an end portion 3051b in a penetration direction. The penetration direction refers to a direction in which the first conductor 3051 penetrates the second semiconductor layer 3050, and is also the thickness direction of the second semiconductor layer 3050. The end portion 3051a of the first conductor 3051 is positioned in the third wiring layer 3060, and the end portion 3051b is positioned in the second wiring layer 3040. Since the first conductor 3051 has a tapered shape in the penetration direction, the diameter of the end portion 3051a is larger than that of the end portion 3051b. Then, the above-described first width Corresponds, for example, to the larger dimension of the end portions of the first conductor 3051 in the penetration direction. More specifically, the first width corresponds to the larger dimension of the dimensions (here, diameter) of the end portion 3051a and the dimension (here, diameter) of the end portion 3051b, that is, to the dimension (here, diameter) of the end portion 3051a. Note that the term “diameter” refers to a distance between side surfaces, regardless of the planar shape of the first conductor 3051. Furthermore, here, the diameter of the end portion 3051a is denoted as a diameter d1.

Similarly, the second conductor 3052 has an end portion 3052a and an end portion 3052b in the penetration direction. The penetration direction refers to a direction in which the second conductor 3052 penetrates the second semiconductor layer 3050, and is also the thickness direction of the second semiconductor layer 3050. The end portion 3052a of the second conductor 3052 is positioned in the third wiring layer 3060, and the end portion 3052b is positioned in the second wiring layer 3040. Since the second conductor 3052 has a tapered shape in the penetration direction, the diameter of the end portion 3052b is larger than that of the end portion 3052a. Then, the above-described second width corresponds, for example, to the larger dimension of the end portions of the second conductor 3052 in the penetration direction. More specifically, the second width corresponds to the larger dimension of the dimensions (here, diameter) of the end portion 3052a and the dimension (here, diameter) of the end portion 3052b, that is, to the dimension (here, diameter) of the end portion 3052b. Note that the term “diameter” refers to a distance between side surfaces, regardless of the planar shape of the second conductor 3052. Furthermore, here, the diameter of the end portion 3052b is denoted as a diameter d2. Then, the diameter d2 of the end portion 3052b is smaller than the diameter dl of the end portion 3051a (d2<d1).

Furthermore, one of the end portion 3051a of the first conductor 3051, which has the first width, and the end portion 3052b of the second conductor 3052, which has the second width, is positioned on the second wiring layer 3040, and the other thereof is positioned on the third wiring layer 3060. In the example illustrated in FIG. 32A, the end portion 3052b is positioned on the second wiring layer 3040, and the end portion 3051a is positioned on the third wiring layer 3060.

The end portions on one side of the first conductor 3051 and the second conductor 3052 are connected to different wirings belonging to a single metal layer provided in a wiring layer on the same side as the end portions on the one side. More specifically, the end portion 3051a of the first conductor 3051 on the third wiring layer 3060 side (one side) and the end portion 3052a of the second conductor 3052 on the third wiring layer 3060 side (one side) are connected to the wirings formed by dividing a single metal layer provided in the third wiring layer 3060 described later, or the wirings formed by embedding a metal film in a groove and removing a surplus portion of the metal film. More specifically, the single metal layer is a metal layer M1 of the third wiring layer 3060 described in a manufacturing method to be described later. Then, the metal layer M1 is divided to form a plurality of wirings 3062 belonging to the metal layer M1. Here, the wiring to which the end portion 3051a is connected is referred to as a wiring 3062a in order to be distinguished from the other wirings, and the wiring to which the end portion 3052a is connected is referred to as a wiring 3062b in order to be distinguished from the other wirings. Furthermore, the single metal layer is a metal layer closest to the second semiconductor layer 3050 in the wiring layer on the same side as the end portion on the one side.

The end portion 3051b of the first conductor 3051 on the second wiring layer 3040 side (the other side) and the end portion 3052b of the second conductor 3052 on the second wiring layer 3040 side (the other side) are connected to the wirings 3042 belonging to the metal layer M1 of the second wiring layer 3040.

### Third Wiring Layer

As illustrated in FIGS. 32A and 32B, the third wiring layer 3060 includes an insulating film 3061, the wirings 3062, a third connection pad 3063, a barrier insulating film 3064, and a silicon cover film 3065. As illustrated in the drawing, the wiring 3062 and the third connection pad 3063 are stacked with the insulating film 3061 interposed therebetween. The third connection pad 3063 faces the surface of the third wiring layer 3060 on a side opposite to the second semiconductor layer 3050 side. The wiring 3062 and the third connection pad 3063 are not limited to this, but may include copper and be formed using a damascene process, for example.

As illustrated in FIG. 32B, the third wiring layer 3060 includes the barrier insulating film 3064 provided at a position overlapping the wiring 3062 belonging to metal layer M1 in the thickness direction. The barrier insulating film 3064 has a function of preventing the diffusion of metal from a side of the barrier insulating film 3064 opposite to the second semiconductor layer 3050 side to a side of the barrier insulating film 3064 on the second semiconductor layer 3050 side. More specifically, the barrier insulating film 3064, although not limited to this, prevents the metal (here, copper) of the wiring formed on, for example, a side of the barrier insulating film 3064 opposite to the second semiconductor layer 3050 from diffusing toward the side of the barrier insulating film 3064 on the second semiconductor layer 3050 side. The barrier insulating film 3064 is a film having an insulating property, and may be, for example, a film containing silicon (Si) and nitrogen (N), a film containing silicon and carbon (C), or a SiCN film containing silicon, carbon, and nitrogen, although not limited to these. Here, the barrier insulating film 3064 is assumed to be a SiCN film.

The silicon cover film 3065 is provided to prevent light emission reflection of the element, and includes a high-melting-point oxide.

### Fourth Wiring Layer

As illustrated in FIG. 32A, the fourth wiring layer 3070 includes an insulating film 3071, wirings 3072, a fourth connection pad 3073, and vias (contacts) 3074. As illustrated in the drawing, the wiring 3072 and the fourth connection pad 3073 are stacked with the insulating film 3071 interposed therebetween. The fourth connection pad 3073 faces the surface of the fourth wiring layer 3070 on a side opposite to the third semiconductor layer 3080 side, and is bonded to the third connection pad 3063. The vias 3074 connect the third semiconductor layer 3080 to the wiring 3072, the wirings 3072 to each other, and the wiring 3072 to the fourth connection pad 3073 or the like. Furthermore, the wiring 3072 and the fourth connection pad 3073 are not limited to this, but may include copper and be formed using a damascene process, for example.

### Third Semiconductor Layer

The third semiconductor layer 3080 includes a semiconductor substrate. The third semiconductor layer 3080 includes a single-crystal silicon substrate of a first conductivity type, for example, a p-type. A plurality of transistors T3 is provided in the third semiconductor layer 3080. More specifically, the transistors T3 are provided in a region of the third semiconductor layer 3080 overlapping the pixel region 3002A and the peripheral region 3002B in plan view.

In the above-described structure, the first semiconductor layer 3020 and the first wiring layer 3030 may be associated with the first layer 2010a of the above-described substrate. The second semiconductor layer 3050 and the second wiring layer 3040 may be associated with the second layer 2010b of the above-described substrate. Furthermore, the third semiconductor layer 3080 and the fourth wiring layer 3070 may be associated with the memory +logic section 2011.

### Application Example to Mobile Body

The technology according to the present disclosure (present technology) can be applied to various products. For example, the technology according to the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

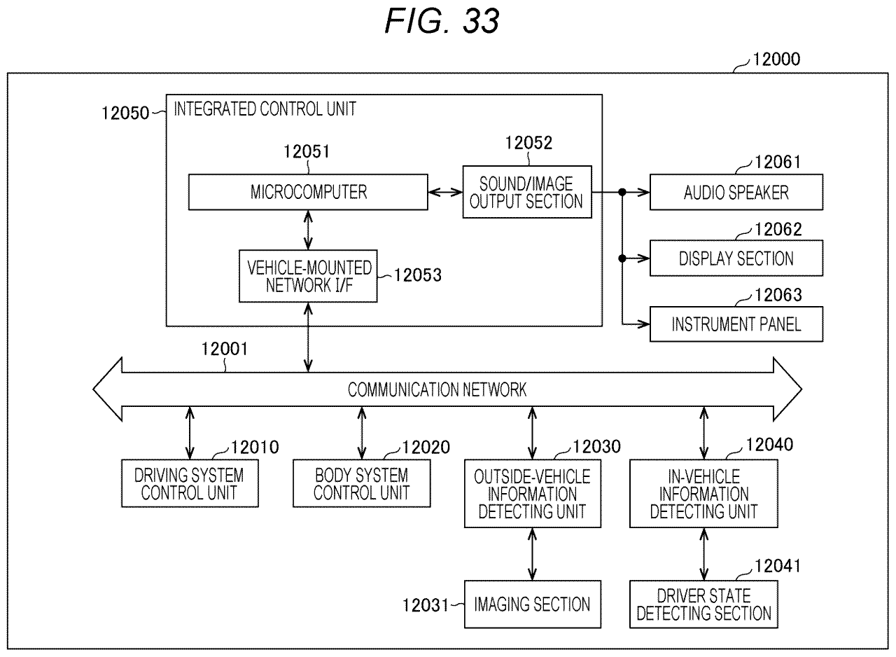

FIG. 33 is a block diagram illustrating a schematic configuration example of a vehicle control system, which is an example of a mobile body control system to which the technology according to the present disclosure can be applied.

The vehicle control system 12000 includes a plurality of electronic control units connected to each other via a communication network 12001. In the example illustrated in FIG. 33, the vehicle control system 12000 includes a driving system control unit. 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 33, an audio speaker 12061, a display section 12062, and an instrument panel 12063 are exemplified as the output device. The display section 12062 may, for example, include at least one of an on-board display and a head-up display.

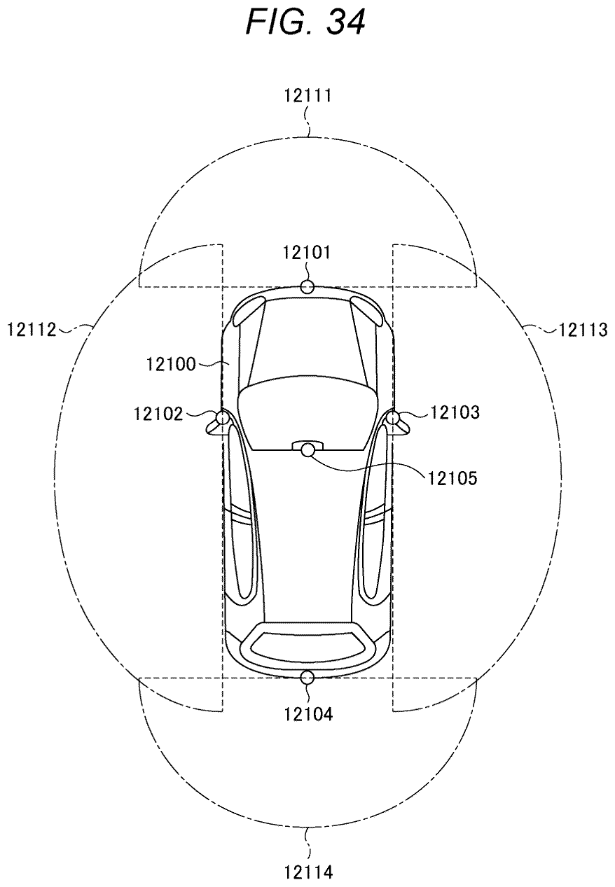

FIG. 34 is a diagram illustrating an example of the installation position of the imaging section 12031.

In FIG. 34, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 34 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging device 1004 in the configuration described above. By applying the technology according to the present disclosure, noise of the imaging device 1004 can be further reduced.

Note that the present technology may have the following configurations.
(1) An imaging device including:
a plurality of photoelectric conversion elements that is arranged in a first direction and a second direction intersecting each other, and accumulates electric charges according to a light amount of incident light;
a plurality of pixel circuits that generates an analog pixel signal according to the electric charges accumulated in the plurality of photoelectric conversion elements;
a signal line that transmits the analog pixel signal output from the two or more pixel circuits arranged in the second direction; and
a clip circuit that clips a voltage of the signal line to a predetermined lower limit voltage level using a power supply voltage line of any of the two or more pixel circuits connected to the signal line.
(2) The imaging device according to (1), further including:
a conversion circuit that performs analog-digital conversion on the analog pixel signal transmitted through the signal line,
in which the conversion circuit includes
a first circuit connected to the signal line, and
a second circuit connected to an output node of the first circuit, and
the first circuit includes the clip circuit.
(3) The imaging device according to (2), in which the conversion circuit includes a current source that generates a current flowing through the signal line, and a current flowing through the clip circuit.
(4) The imaging device according to (2) or (3),
in which the first circuit compares the analog pixel signal with a reference signal, and
the second circuit compares an output signal of the first circuit with a threshold value.
(5) The imaging device according to (4),
in which the first circuit includes a first-stage comparator that compares the analog pixel signal with the reference signal,
the clip circuit includes
a first transistor and a second transistor that are cascode-connected between the power supply voltage line and a reference voltage line of the first-stage comparator,
the first transistor is turned on when a first signal that instructs clipping to the lower limit voltage level reaches a predetermined level, and
the second transistor is turned on when a second signal that instructs selection of the first circuit reaches a predetermined level.
(6) The imaging device according to any one of (2) to (5),
in which the first circuit includes a first input node connected to the power supply voltage line, and a second input node connected to the signal line.
(7) The imaging device according to (6), further including:
a first semiconductor layer in which the plurality of photoelectric conversion elements and the plurality of pixel circuits are arranged;
a second semiconductor layer that is stacked on the first semiconductor layer and in which the first circuit is arranged;
a first bonding member that bonds the first semiconductor layer and the second semiconductor layer and is connected to the first input node; and
a second bonding member that bonds the first semiconductor layer and the second semiconductor layer and is connected to the second input node.
(8) The imaging device according to any one of (2) to (7),
in which the signal line includes a plurality of divided signal lines divided along the second direction,
output nodes of the two or more pixel circuits arranged along the second direction are respectively connected to the plurality of divided signal lines,
the clip circuit is provided for each of the plurality of divided signal lines, and clips, using the power supply voltage line of any of the two or more pixel circuits connected to a corresponding divided signal line, a voltage of the corresponding divided signal line to the predetermined lower limit voltage level, and
the conversion circuit performs analog-digital conversion on the analog pixel signal transmitted through the plurality of divided signal lines.
(9) The imaging device according to (8),
in which the conversion circuit includes
a plurality of the first circuits connected to the plurality of divided signal lines, and
the second circuit connected to output nodes of the plurality of first circuits, and
each of the plurality of first circuits includes the clip circuit.
(10) an Imaging Device Including:
a plurality of photoelectric conversion elements that is arranged in a first direction and a second direction intersecting each other, and accumulates electric charges according to a light amount of incident light;
a plurality of pixel circuits that generates an analog pixel signal according to the electric charges accumulated in the plurality of photoelectric conversion elements;
a signal line that transmits the analog pixel signal output from the two or more pixel circuits arranged in the second direction; and
a conversion circuit that performs analog-digital conversion on the analog pixel signal transmitted through the signal line,
in which the signal line includes a plurality of divided signal lines divided along the second direction,
the conversion circuit includes
a plurality of first circuits connected to the plurality of divided signal lines, and
a second circuit connected to output nodes of the plurality of first circuits, and
the output nodes of the plurality of first circuits are divided into two or more sets, and are connected to the second circuit for each of the sets.
(11) The imaging device according to (10),
in which the conversion circuit includes a first.

selector that connects any one set of the two or more sets to the second circuit.
(12) The imaging device according to (11), further including:
a second selector that selects, for each of the two or more sets, any one of the output nodes of the two or more first circuits belonging to the set, and
the output node of the first circuit selected by the first selector and the second selector is connected to the second circuit.
(13) The imaging device according to (12), further including:
a precharge circuit that precharges the output node of the first circuit that has not been selected by the second selector.
(14) The imaging device according to (13), further including:
a first semiconductor layer in which the plurality of photoelectric conversion elements and the plurality of pixel circuits are arranged;
a second semiconductor layer that is stacked on the first semiconductor layer and in which the plurality of first circuits is arranged; and
a third semiconductor layer that is stacked on the second semiconductor layer and in which the second circuit is arranged,
in which the first selector, the second selector, and the precharge circuit are arranged in the second semiconductor layer.
(15) The imaging device according to (13), further including:
a first semiconductor layer in which the plurality of photoelectric conversion elements and the plurality of pixel circuits are arranged;
a second semiconductor layer that is stacked on the first semiconductor layer and in which the plurality of first circuits is arranged; and
a third semiconductor layer that is stacked on the second semiconductor layer and in which the second circuit is arranged,
in which each of the first selector, the second selector, and the precharge circuit is arranged in the second semiconductor layer or the third semiconductor layer.
(16) The imaging device according to any one of (10) to (15), further including:
a clip circuit that is provided for each of the plurality of divided signal lines, and clips, using the power supply voltage line of any of the two or more pixel circuits connected to a corresponding divided signal line, a voltage of the corresponding divided signal line to a predetermined lower limit voltage level.
(17) The imaging device according to any one of (10) to (16),
in which each of the plurality of first circuits includes a voltage setting circuit that sets a corresponding divided signal line to a predetermined voltage level in a case where the first circuit is not connected to the second circuit.
(18) An imaging device including:
a plurality of photoelectric conversion elements that is arranged in a first direction and a second direction intersecting each other, and accumulates electric charges according to a light amount of incident light;
a plurality of pixel circuits that generates an analog pixel signal according to the electric charges accumulated in the plurality of photoelectric conversion elements;
a signal line that transmits the analog pixel signal output from the two or more pixel circuits arranged in the second direction; and
a conversion circuit that performs analog-digital conversion on the analog pixel signal transmitted through the signal line,
in which the signal line includes a plurality of divided signal lines divided along the second direction,
the conversion circuit includes
a plurality of first circuits connected to the plurality of divided signal lines, and
a second circuit connected to output nodes of the plurality of first circuits, and
each of the plurality of first circuits includes a voltage setting circuit that sets a corresponding divided signal line to a predetermined voltage level in a case where the first circuit is not connected to the second circuit.
(19) The imaging device according to (18),
in which the voltage setting circuit includes a dummy source follower circuit having a same circuit configuration as circuit configurations of an amplifier transistor and a selection transistor that constitute a source follower circuit in the pixel circuit, and
the dummy source follower circuit sets the Corresponding divided signal line to the predetermined voltage level.

Modes of the present disclosure are not limited to the individual embodiments described above, but include various modifications that may be conceived by those skilled in the art, and the effects of the present disclosure are not limited to the contents described above. That is, various additions, modifications, and partial deletions may be made without departing from the conceptual idea and spirit of the present disclosure derived from the matters defined in the claims and equivalents thereof.

### REFERENCE SIGNS LIST

2 Clip circuit
10 Pixel
10a1 Pixel region
10a2 Clip region
10c Pixel circuit
11 Pixel array section
12 Vertical scanning circuit
13 Timing control section
15 Column signal processing section
16 Horizontal scanning circuit
20 Comparator
23 First selector
24 Second selector
25 Precharge circuit
26 Third selector
27 Precharge voltage generator
28 Voltage setting circuit
30 Counter
40 Logic circuit
50 Peripheral circuit
60 Interface circuit
73 First circuit
100 Photoelectric conversion section
210 Second circuit
211 Third circuit
251 Post-stage circuit
1005 Image processing section
1006 Memory
1007 Storage section
1008 Display section
1009 Interface (I/F) unit
1012 Input device
2010a First layer
2010b Second layer
2010c Third layer
2011 First-stage comparator
2011 Logic section
2012 Memory section
2501 Pixel/first-stage comparator section
2501 M (M≥2) pixel/first-stage comparator section
2502 Pixel/first-stage comparator section
3001 Imaging device
3002A Pixel region
3002B Peripheral region

1. An imaging device comprising:
a plurality of photoelectric conversion elements that is arranged in a first direction and a second direction intersecting each other, and accumulates electric charges according to a light amount of incident light;
a plurality of pixel circuits that generates an analog pixel signal according to the electric charges accumulated in the plurality of photoelectric conversion elements;
a signal line that transmits the analog pixel signal output from the two or more pixel circuits arranged in the second direction; and
a clip circuit that clips a voltage of the signal line to a predetermined lower limit voltage level using a power supply voltage line of any of the two or more pixel circuits connected to the signal line.

2. The imaging device according to claim 1, further comprising:
a conversion circuit that performs analog-digital conversion on the analog pixel signal transmitted through the signal line,
wherein the conversion circuit includes
a first circuit connected to the signal line, and
a second circuit connected to an output node of the first circuit, and
the first circuit includes the clip circuit.

3. The imaging device according to claim 2, wherein the conversion circuit includes a current source that generates a current flowing through the signal line, and a current flowing through the clip circuit.

4. The imaging device according to claim 2,
wherein the first circuit compares the analog pixel signal with a reference signal, and
the second circuit compares an output signal of the first circuit with a threshold value.

5. The imaging device according to claim 4,
wherein the first circuit includes a first-stage comparator that compares the analog pixel signal with the reference signal,
the clip circuit includes
a first transistor and a second transistor that are cascode-connected between the power supply voltage line and a reference voltage line of the first-stage comparator,
the first transistor is turned on when a first signal that instructs clipping to the lower limit voltage level reaches a predetermined level, and
the second transistor is turned on when a second signal that instructs selection of the first circuit reaches a predetermined level.

6. The imaging device according to claim 2,
wherein the first circuit includes a first input node connected to the power supply voltage line, and a second input node connected to the signal line.

7. The imaging device according to claim 6, further comprising:
a first semiconductor layer in which the plurality of photoelectric conversion elements and the plurality of pixel circuits are arranged;
a second semiconductor layer that is stacked on the first semiconductor layer and in which the first circuit is arranged;
a first bonding member that bonds the first semiconductor layer and the second semiconductor layer and is connected to the first input node; and
a second bonding member that bonds the first semiconductor layer and the second semiconductor layer and is connected to the second input node.

8. The imaging device according to claim 2,
wherein the signal line includes a plurality of divided signal lines divided along the second direction,
output nodes of the two or more pixel circuits arranged along the second direction are respectively connected to the plurality of divided signal lines,
the clip circuit is provided for each of the plurality of divided signal lines, and clips, using the power supply voltage line of any of the two or more pixel circuits connected to a corresponding divided signal line, a voltage of the corresponding divided signal line to the predetermined lower limit voltage level, and
the conversion circuit performs analog-digital conversion on the analog pixel signal transmitted through the plurality of divided signal lines.

9. The imaging device according to claim 8,
wherein the conversion circuit includes
a plurality of the first circuits connected to the plurality of divided signal lines, and
the second circuit connected to output nodes of the plurality of first circuits, and
each of the plurality of first circuits includes the clip circuit.

10. An imaging device comprising:
a plurality of photoelectric conversion elements that is arranged in a first direction and a second direction intersecting each other, and accumulates electric charges according to a light amount of incident light;
a plurality of pixel circuits that generates an analog pixel signal according to the electric charges accumulated in the plurality of photoelectric conversion elements;
a signal line that transmits the analog pixel signal output from the two or more pixel circuits arranged in the second direction; and
a conversion circuit that performs analog-digital conversion on the analog pixel signal transmitted through the signal line,
wherein the signal line includes a plurality of divided signal lines divided along the second direction,
the conversion circuit includes
a plurality of first circuits connected to the plurality of divided signal lines, and
a second circuit connected to output nodes of the plurality of first circuits, and
the output nodes of the plurality of first circuits are divided into two or more sets, and are connected to the second circuit for each of the sets.

11. The imaging device according to claim 10,
wherein the conversion circuit includes a first selector that connects any one set of the two or more sets to the second circuit.

12. The imaging device according to claim 11, further comprising:
a second selector that selects, for each of the two or more sets, any one of the output nodes of the two or more first circuits belonging to the set, and
the output node of the first circuit selected by the first selector and the second selector is connected to the second circuit.

13. The imaging device according to claim 12, further comprising:
a precharge circuit that precharges the output node of the first circuit that has not been selected by the second selector.

14. The imaging device according to claim 13, further comprising:
a first semiconductor layer in which the plurality of photoelectric conversion elements and the plurality of pixel circuits are arranged;
a second semiconductor layer that is stacked on the first semiconductor layer and in which the plurality of first circuits is arranged; and
a third semiconductor layer that is stacked on the second semiconductor layer and in which the second circuit is arranged,
wherein the first selector, the second selector, and the precharge circuit are arranged in the second semiconductor layer.

15. The imaging device according to claim 13, further comprising:
a first semiconductor layer in which the plurality of photoelectric conversion elements and the plurality of pixel circuits are arranged;
a second semiconductor layer that is stacked on the first semiconductor layer and in which the plurality of first circuits is arranged; and
a third semiconductor layer that is stacked on the second semiconductor layer and in which the second circuit is arranged,
wherein each of the first selector, the second selector, and the precharge circuit is arranged in the second semiconductor layer or the third semiconductor layer.

16. The imaging device according to claim 10, further comprising:
a clip circuit that is provided for each of the plurality of divided signal lines, and clips, using the power supply voltage line of any of the two or more pixel circuits connected to a corresponding divided signal line, a voltage of the corresponding divided signal line to a predetermined lower limit voltage level.

17. The imaging device according to claim 10,
wherein each of the plurality of first circuits includes a voltage setting circuit that sets a corresponding divided signal line to a predetermined voltage level in a case where the first circuit is not connected to the second circuit.

18. An imaging device comprising:
a plurality of photoelectric conversion elements that is arranged in a first direction and a second direction intersecting each other, and accumulates electric charges according to a light amount of incident light;
a plurality of pixel circuits that generates an analog pixel signal according to the electric charges accumulated in the plurality of photoelectric conversion elements;
a signal line that transmits the analog pixel signal output from the two or more pixel circuits arranged in the second direction; and
a conversion circuit that performs analog-digital conversion on the analog pixel signal transmitted through the signal line,
wherein the signal line includes a plurality of divided signal lines divided along the second direction,
the conversion circuit includes
a plurality of first circuits connected to the plurality of divided signal lines, and
a second circuit connected to output nodes of the plurality of first circuits, and
each of the plurality of first circuits includes a voltage setting circuit that sets a corresponding divided signal line to a predetermined voltage level in a case where the first circuit is not connected to the second circuit.

19. The imaging device according to claim 18,
wherein the voltage setting circuit includes a dummy source follower circuit having a same circuit configuration as circuit configurations of an amplifier transistor and a selection transistor that constitute a source follower circuit in the pixel circuit, and
the dummy source follower circuit sets the corresponding divided signal line to the predetermined voltage level.
